(19) United States
(12) Patent Application Publication
(10) Pub. No.: US 2026/0371576 A1
(43) Pub. Date: Nov. 19, 2026

(54) SEMICONDUCTOR DEVICE, MANUFACTURING METHOD THEREOF, AND MEMORY SYSTEM

(71) Applicant: Yangtze Memory Technologies Co., Ltd., Wuhan (CN)

(72) Inventors: Danyang Wei, Wuhan (CN); Shiqi Huang, Wuhan (CN); Feng Wang, Wuhan (CN); Liang Chen, Wuhan (CN); Wei Liu, Wuhan (CN); Lei Huang, Wuhan (CN); Zongliang Huo, Wuhan (CN)

(21) Appl. No.: 19/578,740

(22) Filed: Mar. 25, 2026

(30) Foreign Application Priority Data
May 13, 2025 (CN) 202510615234.5

(51) Int. Cl. H10B 12/00

(52) U.S. Cl. CPC H10B 12/50; H10B 12/33

(57) ABSTRACT

A semiconductor device, a manufacturing method thereof, and a memory system are provided. The semiconductor device includes a first semiconductor structure including a memory block and a second semiconductor structure on a first side of the first semiconductor structure in a first direction. The second semiconductor structure includes two first portions, a second portion, and a third portion. The two first portions are on a second side of the memory block in the first direction. The second portion is on a third side of the memory block in the first direction and on a fourth side of the first portion in the second or third direction. The third portion is on a fifth side of the memory block in the first direction. The two first portions are spaced apart from each other in the third direction. The third portion is between the two first portions. The first, second, and third portions include different circuits.

### CROSS-REFERENCE TO RELATED APPLICATIONS

This application claims the benefit of priority to Chinese Application No. 202510615234.5, filed on May 13, 2025, which is hereby incorporated by reference in its entirety.

### TECHNICAL FIELD

The present disclosure relates to the field of semiconductor technologies, and in particular, to a semiconductor device, a method for manufacturing the semiconductor device, and a memory system.

### BACKGROUND

With the rapid advancement of artificial intelligence, big data, the Internet of Things, mobile communications, mobile devices, and cloud storage, the performance and processing requirements for semiconductor devices, including three-dimensional semiconductor memory devices, have increased significantly.

### SUMMARY

One aspect of the present disclosure provides a semiconductor device. The semiconductor device comprises a first semiconductor structure and a second semiconductor structure. The first semiconductor structure comprises a memory block. The second semiconductor structure is located on a first side of the first semiconductor structure in a first direction. The second semiconductor structure comprises two first portions, a second portion, and a third portion. The two first portions are located on a second side of the memory block in the first direction. The second portion is located on a third side of the memory block in the first direction, and is located on a fourth side of the first portion in the second direction or the third direction. The third portion is located on a fifth side of the memory block in the first direction. The two first portions are spaced apart from each other in the third direction. The third portion is located between the two first portions. The first portion, the second portion, and the third portion comprise different circuits. The first direction, the second direction, and the third direction intersect with each other.

In an implementation, the second semiconductor structure comprises two second portions comprising the second portion and spaced apart from each other in the second direction. The two second portions are located between the two first portions.

In an implementation, the second portion is located between the two first portions that are adjacent in the third direction.

In an implementation, a dimension of the first portion in the second direction is the same as a dimension of the memory block in the second direction.

In an implementation, the first portion comprises a first end and a second end opposite to each other in the second direction. A dimension of the first end in the third direction is different from a dimension of the second end in the third direction.

In an implementation, a dimension of the first portion in the second direction is the same as a dimension of the third portion in the second direction. A part of the third portion is located on at least a sixth side of the second portions in the third direction, and a remaining part of the third portion is located between two second portions.

In an implementation, the second semiconductor structure comprises two second portions comprising the second portion and spaced apart from each other in the second direction. The two second portions are located on two sides of the first portion and the third portion in the second direction, respectively.

In an implementation, a dimension of the first portion in the second direction is the same as a dimension of the third portion in the second direction.

In an implementation, the second portion is located at an end of the first portion in the second direction.

In an implementation, a dimension of the first portion in the second direction is smaller than a dimension of the memory block in the second direction. A dimension of the second portion in the third direction is the same as a dimension of the memory block in the third direction.

In an implementation, the first portion comprises a first end and a second end opposite to each other in the second direction. A dimension of the first end in the third direction is the same as a dimension of the second end in the third direction.

In an implementation, the first portion further comprises an intermediate portion between the first end and the second end. A dimension of the first end in the third direction is greater than a dimension of the intermediate portion in the third direction.

In an implementation, the semiconductor device further comprises a first interconnect layer, a second interconnect layer, and a conductive structure. The first interconnect layer is located between the first semiconductor structure and the second semiconductor structure and connected to a circuit in the third portion. The second interconnect layer is located on a sixth side of the second semiconductor structure facing away from the first semiconductor structure. The conductive structure extends through the second semiconductor structure in the first direction and is connected to the first interconnect layer and the second interconnect layer.

In an implementation, the dimension of the first portion in the second direction is greater than its dimension in the third direction. A dimension of the second portion in the third direction is greater than a dimension of the second portion in the second direction.

In an implementation, a memory block comprises a semiconductor body, a gate structure, and a bit line. The gate structure is located on a sixth side of the semiconductor body in the third direction. A dimension of the gate structure in the second direction is greater than a dimension of the gate structure in the third direction. The bit line is located on a seventh side of the semiconductor body in the first direction. A dimension of the bit line in the third direction is greater than a dimension of the bit line in the second direction.

In an implementation, a circuit in the first portion comprises a sense amplifier circuit and a circuit in the second portion comprises a word line driver circuit. The sense amplifier circuit is connected to the bit line, and the word line driver circuit is connected to the gate structure.

In an implementation, the semiconductor device includes a dynamic random access memory.

Another aspect of the present disclosure provides another semiconductor device. The semiconductor device comprises a first semiconductor structure and a second semiconductor structure. The first semiconductor structure comprises a first memory block and a second memory block adjacent to each other. The second semiconductor structure is located on a first side of the first semiconductor structure in the first direction. The second semiconductor structure comprises a first portion, a second portion, and a third portion. The first portion is located on a second side of the first memory block in the first direction. The second portion is located on a third side of the second memory block in the first direction. The third portion comprises a first sub-portion and a second sub-portion. The first sub-portion is located on a fourth side of the first memory block in the first direction. The second sub-portion is located on a fifth side of the second memory block in the first direction. The first memory block and the second memory block are adjacent to each other in the second direction or the third direction. The first portion, the second portion, and the third portion comprise different circuits. The first direction, the second direction, and the third direction intersect with each other.

In an implementation, the first sub-portion is further located on two sides of the first portion in the third direction.

In an implementation, the dimension of the first sub-portion in the second direction is the same as the dimension of the first portion in the second direction.

In an implementation, the second semiconductor structure comprises two second portions comprising the second portion and spaced apart from each other in the second direction. A part of the second sub-portion is located on at least a sixth side of the second portions in the third direction, and a remaining part of the second sub-portion is located between two second portions.

In an implementation, a dimension of the second portion in the third direction is smaller than a dimension of the second memory block in the third direction.

In an implementation, the second semiconductor structure comprises two first portions comprising the first portion and spaced apart from each other in the third direction. A dimension of the first sub-portion in the second direction is the same as a dimension of the first portion in the second direction.

In an implementation, the second semiconductor structure comprises two second portions comprising the second portion and spaced apart from each other in the second direction. The second sub-portion is located between the two second portions. A dimension of the second portion in the third direction is the same as a dimension of the second memory block in the third direction.

In an implementation, a dimension of the first portion in the second direction is the same as a dimension of the first memory block in the second direction.

In an implementation, the semiconductor device further comprises a first interconnect layer, a second interconnect layer, and a conductive structure. The first interconnect layer is located between the first semiconductor structure and the second semiconductor structure and connected to a circuit in the third portion. The second interconnect layer is located on a sixth side of the second semiconductor structure facing away from the first semiconductor structure. The conductive structure extends through the second semiconductor structure in the first direction and is connected to the first interconnect layer and the second interconnect layer.

In an implementation, the first memory block and the second memory block comprise semiconductor bodies, gate structures, and bit lines. The gate structure is located on a sixth side of the semiconductor body in the third direction. A dimension of the gate structure in the second direction is greater than a dimension of the gate structure in the third direction. The bit line is located on a seventh side of the semiconductor body in the first direction. A dimension of the bit line in the third direction is greater than a dimension of the bit line in the second direction.

In an implementation, a circuit in the first portion comprises a sense amplifier circuit and a circuit in the second portion comprises a word line driver circuit. The sense amplifier circuit is connected to the bit line, and the word line driver circuit is connected to the gate structure.

In an implementation, the semiconductor device includes a dynamic random access memory.

Another aspect of the present disclosure provides a method of manufacturing a semiconductor device. The method comprises forming a first semiconductor structure comprising a memory block and forming a second semiconductor structure. The second semiconductor structure is located on a first side of the first semiconductor structure in the first direction. The second semiconductor structure comprises two first portions, a second portion, and a third portion. The two first portions are located on a second side of the memory block in the first direction. The second portion is located on a third side of the memory block in the first direction, and is located on a fourth side of the first portion in the second direction or the third direction. The third portion is located on a fifth side of the memory block in the first direction. The two first portions are spaced apart from each other in the third direction, and the third portion is located between the two first portions. The first portion, the second portion, and the third portion comprise different circuits. The first direction, the second direction, and the third direction intersect with each other.

In an implementation, forming the first semiconductor structure comprises forming the first semiconductor structure on a sixth side of the second semiconductor structure in the first direction.

In an implementation, the method comprises bonding the first semiconductor structure and the second semiconductor structure.

In an implementation, the method further comprises: forming a first interconnect layer on a sixth side of the second semiconductor structure in the first direction, where the first interconnect layer is connected to a circuit in the third portion. Forming the first semiconductor structure on a seventh side of the second semiconductor structure in the first direction comprises: forming the first semiconductor structure on an eighth side of the first interconnect layer in the first direction.

In an implementation, the method further comprises: forming a first bonding layer on a sixth side of the first semiconductor structure in a direction opposite to the first direction; forming a first interconnect layer on a seventh side of the second semiconductor structure in the first direction, where the first interconnect layer is connected to the circuit in the third portion; and forming a second bonding layer located on an eighth side of the first interconnect layer in the first direction. Bonding the first semiconductor structure and the second semiconductor structure comprises bonding the first bonding layer and the second bonding layer.

In an implementation, forming the first semiconductor structure comprises: forming a semiconductor body; forming a gate structure, where the gate structure is located on a sixth side of the semiconductor body in a third direction, and a dimension of the gate structure in the second direction is greater than a dimension of the gate structure in the third direction; and forming a bit line, where the bit line is located on a seventh side of the semiconductor body in a first direction, and a dimension of the bit line in the second direction is less than the dimension of the bit line in the third direction.

Another aspect of the present disclosure provides another method of manufacturing a semiconductor device. The method comprises: forming a first semiconductor structure comprising a first memory block and a second memory block adjacent to each other, and forming a second semiconductor structure. The second semiconductor structure is located on a first side of the first semiconductor structure in the first direction. The second semiconductor structure comprises a first portion, a second portion, and a third portion. The first portion is located on a second side of the first memory block in the first direction. The second portion is located on a third side of the second memory block in the first direction. The third portion comprises a first sub-portion and a second sub-portion. The first sub-portion is located on a fourth side of the first memory block in the first direction, and the second sub-portion is located on a fifth side of the second memory block in the first direction. The first memory block and the second memory block are adjacent to each other in the second direction or the third direction. The first portion, the second portion, and the third portion comprise different circuits. The first direction, the second direction, and the third direction intersect with each other.

In an implementation, forming the first semiconductor structure comprises forming the first semiconductor structure on a sixth side of the second semiconductor structure in the first direction.

In an implementation, the method comprises bonding the first semiconductor structure and the second semiconductor structure.

In an implementation, the method further comprises: forming a first interconnect layer on a sixth side of the second semiconductor structure in the first direction, where the first interconnect layer is connected to a circuit in the third portion. Forming the first semiconductor structure on a seventh side of the second semiconductor structure in the first direction comprises: forming the first semiconductor structure on an eighth side of the first interconnect layer in the first direction.

In an implementation, the method further comprises: forming a first bonding layer on a sixth side of the first semiconductor structure in a direction opposite to the first direction; forming a first interconnect layer on a seventh side of the second semiconductor structure in the first direction, where the first interconnect layer is connected to the circuit in the third portion; and forming a second bonding layer located on an eighth side of the first interconnect layer in the first direction. Bonding the first semiconductor structure and the second semiconductor structure comprises bonding the first bonding layer and the second bonding layer.

In an implementation, forming the first semiconductor structure comprises: forming a semiconductor body; forming a gate structure, where the gate structure is located on a sixth side of the semiconductor body in a third direction, and a dimension of the gate structure in the second direction is greater than a dimension of the gate structure in the third direction; and forming a bit line, where the bit line is located on a seventh side of the semiconductor body in a first direction, and a dimension of the bit line in the second direction is less than the dimension of the bit line in the third direction.

Another aspect of the present disclosure provides a memory system. The memory system comprises the semiconductor device as described above and a controller coupled to the semiconductor device and configured to control the semiconductor device to store data.

### BRIEF DESCRIPTION OF THE DRAWINGS

Other features, objects, and advantages of the present disclosure will become more apparent from the following detailed description of non-limiting implementations in conjunction with the accompanying drawings. In the drawings:

FIG. 1 is a schematic diagram of a composition structure of a DRAM, according to some implementations of the present disclosure;

FIG. 2 is a schematic circuit of a memory cell at area A in FIG. 1, according to some implementations of the present disclosure;

FIG. 3 is a schematic structural diagram of a semiconductor device, according to some implementations of the present disclosure;

FIG. 4 is a schematic diagram of an arrangement of a first portion, another first portion, a second portion, another second portion, and a third portion, according to some implementations of the present disclosure;

FIG. 5 is a schematic diagram of a composition structure of a first semiconductor structure, according to some implementations of the present disclosure;

FIG. 6 is an enlarged view of area B in FIG. 5, according to some implementations of the present disclosure;

FIG. 7 is a schematic structural diagram of a transistor, according to some implementations of the present disclosure;

FIG. 8 is a schematic arrangement diagram of a first portion, a second portion, and a third portion corresponding to four memory blocks arranged in an array in a second direction and a third direction, according to some implementations of the present disclosure;

FIG. 9 is a schematic diagram of an arrangement of a first portion, a second portion, and a third portion corresponding to four memory blocks arranged in an array in a second direction and a third direction, according to some implementations of the present disclosure;

FIG. 10 is a schematic diagram of an arrangement of a first portion, a second portion, and a third portion corresponding to four memory blocks arranged in an array in a second direction and a third direction, according to some implementations of the present disclosure;

FIG. 11 is an enlarged view of area C in FIG. 6, according to some implementations of the present disclosure;

FIG. 12 is a schematic diagram of an arrangement of a first portion, a second portion, and a third portion corresponding to four memory blocks arranged in an array in a second direction and a third direction, according to some implementations of the present disclosure;

FIG. 13 is a schematic diagram of circuit routings in a first interconnect layer and a third portion, according to some implementations of the present disclosure;

FIG. 14 is a schematic diagram of an arrangement of a first portion, a second portion, and a third portion corresponding to four memory blocks arranged in an array in a second direction and a third direction, according to some implementations of the present disclosure;

FIG. 15 is a schematic structural diagram of a semiconductor device, according to some implementations of the present disclosure;

FIG. 16 is a flowchart of a method of manufacturing a semiconductor device, according to some implementations of the present disclosure;

FIG. 17 is a schematic structural diagram after formation of a second semiconductor structure and a first interconnect layer, according to some implementations of the present disclosure;

FIG. 18 is a schematic structural diagram after formation of a first semiconductor structure and a substrate, according to some embodiments of the present disclosure;

FIG. 19 is a schematic structural diagram after formation of a second interconnect layer, a conductive structure, and a pad structure, according to some implementations of the present disclosure;

FIGS. 20 to 22 are diagrams of process operations for manufacturing a semiconductor device, according to some implementations of the present disclosure; and

FIG. 23 is an example block diagram of a system with a memory system, according to some implementations of the present disclosure.

### LIST OF REFERENCE NUMERALS

Z, first direction; X, second direction; Y, third direction; 1000, 2000, semiconductor device; 1100, first semiconductor structure; 1110, memory block; 1111, transistor; 1111-1, semiconductor body; 1111-2, gate structure; 1113, bit line; 1112, capacitor; 1110-1, first memory block; 1110-2, second memory block; 1200, second semiconductor structure; 1211, 1212, first portion; 1210-1, first end; 1210-2, second end; 1210-3, intermediate portion; 1221, 1222, second portion; 1230, third portion; 1231, first sub-portion; 1232, second sub-portion; 1240, isolation structure; 1300, first interconnect layer; 1310, 1320, interconnect line; 1400, second interconnect layer; 1500, conductive structure; 1600, pad structure; 1700, substrate; 2100, first bonding layer; 2200, second bonding layer; 100, semiconductor layer.

### DETAILED DESCRIPTION

For a better understanding of the present disclosure, various aspects of the present disclosure will be described in more detail with reference to the accompanying drawings. It should be understood that these detailed descriptions are merely descriptions of implementations of the present disclosure, and do not limit the scope of the present disclosure in any way.

As used herein, ordinal terms such as “first,” “second,” “third,” and the like are employed solely as identifiers to distinguish one element, feature, structure, direction, or side from another, and do not imply any limitation, priority, sequence, order, hierarchy, or relative importance unless explicitly stated otherwise. Accordingly, a “first” semiconductor structure may alternatively be referred to as a “second” semiconductor structure, and a “first” direction may alternatively be referred to as a “second” direction, without departing from the teachings or scope of the present disclosure. Likewise, a “first” side may be referred to as a “second” side, a “third” side, or any other side, including, without limitation, a top side, bottom side, left side, right side, or combinations thereof, and any such relabeling of ordinal descriptors does not alter the structural, functional, or spatial relationships described herein. The use of such ordinal terminology is for convenience of description only and is not intended to be limiting in any manner.

The drawings are schematic representations provided for purposes of illustration only. The relative thicknesses, dimensions, proportions, and shapes of elements may be exaggerated, reduced, simplified, or otherwise modified for clarity and convenience of depiction. Accordingly, the drawings are not necessarily drawn to scale and are not intended to limit the scope of the present disclosure in any respect.

As used herein, the terms “approximately,” “about,” and similar expressions denote reasonable tolerances, variations, and deviations that would be understood by a person of ordinary skill in the art, including but not limited to measurement error, manufacturing tolerances, material properties, environmental influences, and rounding. Such terms are intended to encompass both stated values and equivalent ranges consistent with the technical context.

Unless expressly stated otherwise, positional terms such as “on,” “over,” “above,” “under,” “below,” and similar spatial descriptors are to be interpreted broadly. Such terms encompass both direct and indirect relationships. For example, “on” or “over” includes both direct contact and arrangements in which one or more intervening elements, layers, or structures are present. Conversely, where direct contact is intended, such contact may be expressly stated. The absence of an intervening element should not be implied unless explicitly required.

The terms “comprise,” “comprises,” “comprising,” “include,” “includes,” and “including” are open-ended and indicate the presence of stated features, elements, components, steps, or groups thereof, but do not exclude the presence or addition of other features, elements, components, steps, or groups. The expression “at least one of,” when followed by a list of elements, refers to any one or any combination of the listed elements. The term “may” is permissive and indicates that certain embodiments include the described feature, while others may omit it. The term “exemplary” denotes an example and does not imply preference, advantage, or limitation.

The implementations described herein are presented with reference to schematic illustrations and representative embodiments. The disclosure is not limited to the specific configurations, shapes, dimensions, orientations, or arrangements shown. Rather, the scope of the present disclosure encompasses equivalent structures, functional equivalents, substitutions, modifications, and variations that achieve substantially the same result, including variations arising from design choice, manufacturing processes, or material characteristics. The spatial positioning of elements in the drawings is illustrative and non-limiting.

Unless otherwise expressly defined, all terms (including technical and scientific terms) used herein have the meanings commonly understood by a person of ordinary skill in the art to which this disclosure pertains. Dictionary definitions may be considered for interpretive guidance but shall not supersede the meaning of terms as understood in the relevant technical field and context. No term shall be interpreted in an unduly narrow, idealized, or restrictive manner absent an explicit definition herein.

As used herein, the term “layer” refers broadly to a material portion or region having a measurable dimension in at least one direction. A layer may be homogeneous or heterogeneous, continuous or discontinuous, planar, non-planar, conformal, tapered, or otherwise contoured. A layer may be disposed on, over, under, between, or within other structures and may extend horizontally, vertically, obliquely, or along curved or irregular surfaces.

The terms “contact,” “connected,” and “coupled” encompass direct and indirect relationships unless expressly stated otherwise. Thus, elements described as being in contact, connected, or coupled may be directly joined or may be joined through one or more intermediate elements, layers, conductive paths, or other structures.

The various implementations described herein may be combined in whole or in part unless such combination is explicitly stated to be incompatible. Features described in connection with one embodiment may be incorporated into other embodiments, and such combinations are expressly contemplated. Method steps described herein need not be performed in the order presented unless expressly required. Steps may be performed sequentially, concurrently, in parallel, repetitively, or in any suitable order consistent with the disclosed functionality.

Directional references such as a first direction (Z), a second direction (X), and a third direction (Y) are provided for convenience of description only. Such directions may be orthogonal, oblique, intersecting, non-intersecting, or otherwise oriented relative to one another. References to perpendicularity or intersection are illustrative examples and are not limiting unless expressly required. Any described directional relationship may be modified without departing from the scope of the present disclosure.

The semiconductor device described herein may include one or more memory structures and/or memory technologies, including but not limited to random access memory (RAM). Suitable RAM technologies may include, without limitation, dynamic random access memory (DRAM), synchronous DRAM (SDRAM), static random access memory (SRAM), double data rate SDRAM (including DDR, DDR2, DDR3, DDR4, DDR5, and subsequent generations), phase change RAM (PRAM), magnetic RAM (MRAM), resistive RAM (RRAM), and other volatile or non-volatile memory technologies now known or later developed. The semiconductor device may incorporate any single memory type or any combination of multiple memory types within the scope of the present disclosure. In certain illustrative embodiments, the semiconductor device includes DRAM. For purposes of clarity and convenience of explanation, the embodiments described below are presented primarily in the context of DRAM structures and processes. However, such description is exemplary only and shall not be construed as limiting, as the disclosed structures, materials, arrangements, and fabrication techniques may be applied to other memory architectures and semiconductor devices consistent with the teachings of the present disclosure.

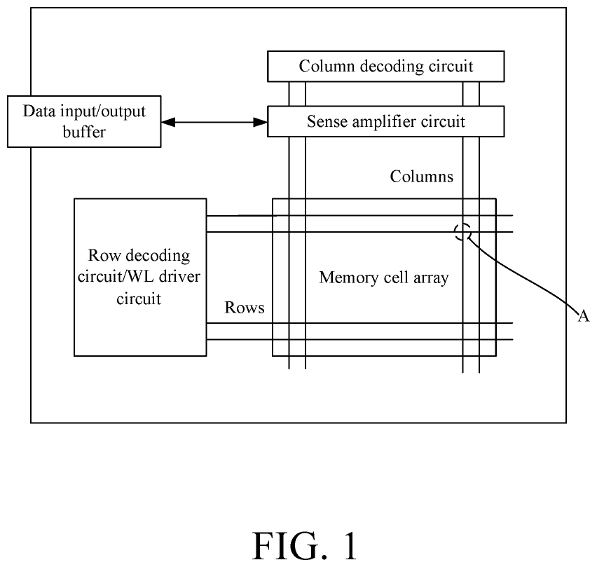

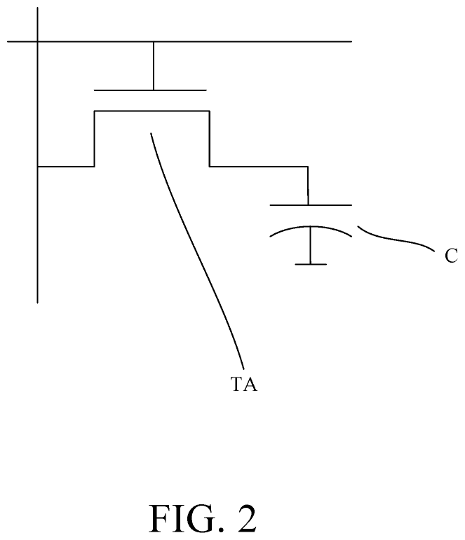

FIG. 1 is a schematic diagram of a composition structure of a DRAM, according to some embodiments of the present disclosure. FIG. 2 is a schematic circuit of the memory cell at area A in FIG. 1.

The DRAM may include a memory cell array, word lines (rows), bit lines (columns), sense amplifier circuits, word line driver circuits, row decoding circuits, column decoding circuits, and data input/output buffers, etc. The memory cell array may include a plurality of memory cells arranged in an array. As shown in FIG. 2, the memory cell may include one array transistor TA and one capacitor C. The main operation principle of the memory cell is to use the amount of charges stored in the capacitor to represent whether a binary bit is l or 0. The memory cells are arranged in an array, which can be regarded as a typical network structure. The memory cell array may specify addresses in rows and columns. For example, each memory cell may be independently accessed by specifying the intersection of a row and a column (by specifying a row address and a column address of the DRAM), and read, write, or refresh data stored therein.

The sense amplifier circuit may be connected to a plurality of bit lines (columns) to sense a low power signal from the bit lines representing a data bit (l or 0) stored in the memory cell and amplify the small voltage swing to a recognizable logic level so that the data can be correctly interpreted by logic cells outside the DRAM. The word line driver circuit may be connected to a plurality of word lines (rows) to apply corresponding driving voltages to the selected/deselected word lines. The row decode circuit may select a word line to select a row of memory cells to access in response to an address input to the row decode circuit. The row decode circuit may decode an input address and enable (activate) a word line corresponding to the decoded address. The column decode circuit may select one or more bit lines to input the output data of user to a portion of the row of memory cells corresponding to the selected word line.

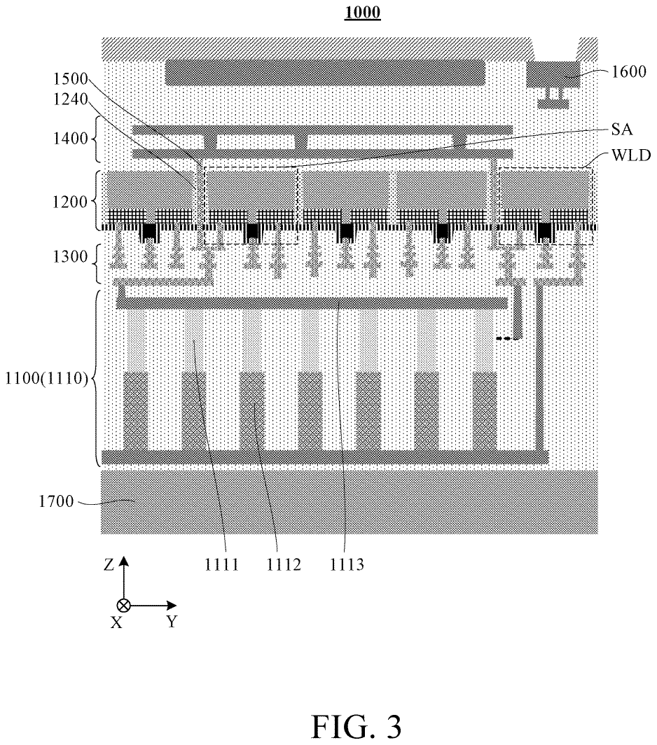

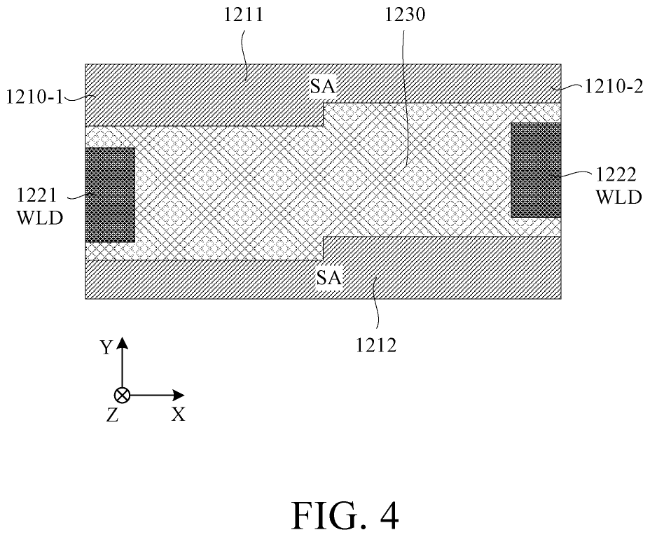

FIG. 3 is a schematic structural diagram of a semiconductor device 1000, according to some embodiments of the present disclosure. FIG. 4 is a schematic diagram of an arrangement of a first portion 1211, a first portion 1212, a second portion 1221, a second portion 1222, and a third portion 1230, according to some embodiments of the present disclosure.

As shown in FIGS. 3 and 4, the semiconductor device 1000 may include a first semiconductor structure 1100 and a second semiconductor structure 1200. The second semiconductor structure 1200 may be located at a side of the first semiconductor structure 1100 in the first direction Z. The first semiconductor structure 1100 may include a memory block 1110. The second semiconductor structure 1200 may include two first portions such as a first portion 1211 and a first portion 1212, a second portion 1221 (or a second portion 1222), and a third portion 1230. The first portion 1211, the first portion 1212, the second portion 1221 (or the second portion 1222), and the third portion 1230 may all be located on a side of the memory block 1110 in the first direction Z.

In an implementation, as shown in FIG. 4, the first portion 1211 and the first portion 1212 may be spaced apart from each other in the third direction Y. The second portion 1221 (or the second portion 1222) may be located on a side of the first portion 1211 (or the first portion 1212) in the third direction Y. The third portion 1230 may be located between the first portion 1211 and the first portion 1212. The first portion 1211 (and the first portion 1212), the second portion 1221 (or the second portion 1222), and the third portion 1230 may include different circuits. For example, the first portion 1211 (and the first portion 1212) may include a sense amplifier circuit SA. The second portion 1221 (or the second portion 1222) may include a word line driver circuit WLD.

In the present disclosure, the first portion, the second portion, and the third portion are all arranged on a side of the memory block 1110 in the first direction Z, which facilitates a suitable layout of the arrangement positions of the first portion, the second portion, and the third portion, and a reduction of the overall dimension of the second semiconductor structure 1200, thereby improving the overall performance of the semiconductor device.

In addition, the two first portions are spaced apart from each other in the third direction Y, and the second portion is located on a side of the first portion in the third direction Y, which facilitates a more concentrated space occupied by the third portion on the basis that the first portion, the second portion, and the third portion are all located on a side of the memory block 1110 in the first direction Z, thereby reducing the layout difficulty of circuits in the third portion.

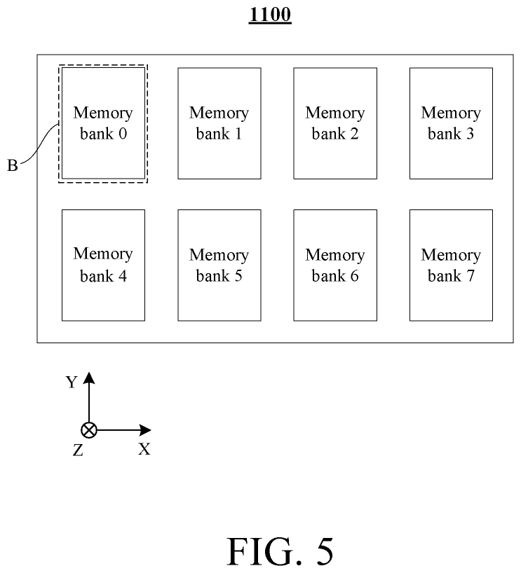

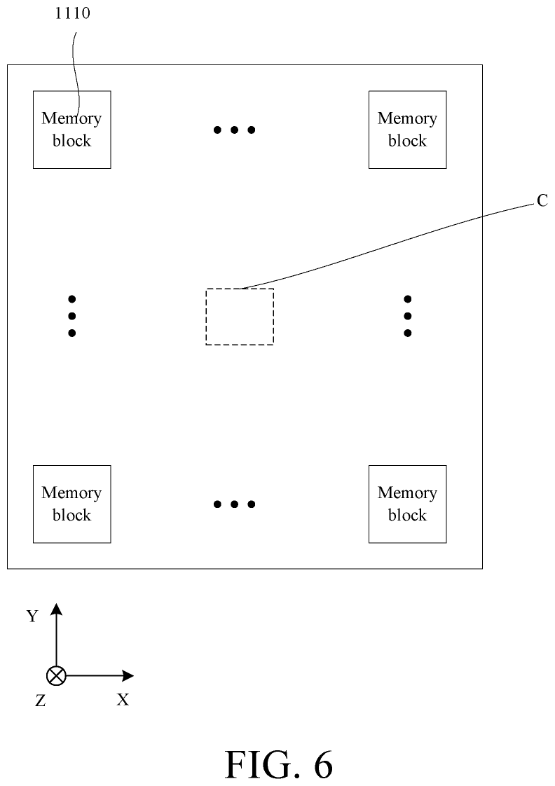

FIG. 5 is a schematic diagram of a composition structure of a first semiconductor structure 1100, according to some embodiments of the present disclosure. FIG. 6 is an enlarged view of area B in FIG. 5.

As shown in FIG. 5, the first semiconductor structure 1100 may include a memory cell array, where the memory cell array may include a plurality of memory banks. For example, as shown in FIG. 5, the memory cell array may include eight memory banks such as memory bank 0, memory bank 1, memory bank 2, memory bank 3, memory bank 4, memory bank 5, memory bank 6, and memory bank 7. Each memory bank may include a plurality of memory blocks. For example, as shown in FIG. 6, memory bank 0 may include a plurality of memory blocks 1110. The plurality of memory blocks 1110 may be arranged in an array in the second direction X and the third direction Y.

The number of memory banks illustrated herein is provided for purposes of example only and is not intended to be limiting. The semiconductor device may include any suitable number of memory banks, and the quantity, configuration, and organization of the memory banks may be selected or adjusted based on design requirements, performance considerations, manufacturing constraints, or other implementation-specific factors. Variations in the number or arrangement of memory banks are within the scope of the present disclosure.

Further, it should be understood that the plurality of memory blocks 1110 may be spaced apart. Each memory block 1110 may include memory cells, word lines, and bit lines 1113 (see FIG. 3, which will be described in detail below). The circuits in the first portion and the second portion may be configured to control word lines and bit lines in their corresponding memory blocks.

For example, the two first portions, the second portion, and the third portion may be located on a side of one memory block 1110 in the first direction Z. For example, the two first portions, the second portion and the third portion may overlap with the projection of one memory block 1110 in the first direction Z. In other words, the two first portions, the second portion and the third portion may be located directly below or directly above one memory block 1110 in the first direction Z. For example, as shown in FIG. 4, the first portion 1211, the first portion 1212, the second portion 1221 (or the second portion 1222), and the third portion 1230 may all be located directly below or directly above one memory block 1110 in the first direction Z.

In an implementation, as shown in FIG. 3, the memory block 1110 may include memory cells and bit lines 1113, where the memory cell may include transistors 1111 and capacitors 1112. A plurality of memory cells may be arranged in an array in the second direction X and the third direction Y.

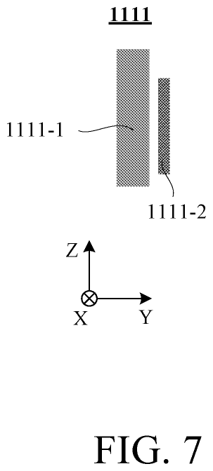

FIG. 7 is a schematic structural diagram of a transistor 1111, according to some embodiments of the present disclosure. The transistor 1111 can include a semiconductor body 1111-1 and a portion of the gate structure 1111-2 corresponding to the semiconductor body 1111-1.

The semiconductor body 1111-1 may have a cubic shape. It is understood that the semiconductor body 1111-1 may have any suitable three-dimensional shape, such as a polyhedron shape or a cylinder shape. That is, a cross-section of the semiconductor body 1111-1 in a plan view (e.g., in an X-Y plane) may have a square shape, a rectangular shape (or a trapezoidal shape), a circular shape (or an elliptical shape), or any other suitable shape. The memory block 1110 may include a plurality of semiconductor bodies 1111-1. The plurality of semiconductor bodies 1111-1 are spaced apart from each other and arranged along the second direction X and the third direction Y. In an implementation, the material of the semiconductor body 1111-1 may include at least one of monocrystalline silicon, polycrystalline silicon, monocrystalline germanium, a III-V compound semiconductor material, a II-VI compound semiconductor material, or other semiconductor materials known in the art.

The semiconductor body 1111-1 and the gate structure 1111-2 may be configured to jointly form a vertical transistor, where the semiconductor body 1111-1 may be configured to form active regions of multiple channels in the vertical transistor. The gate structure 1111-2 may be located on at least a sidewall of the semiconductor body 1111-1, that is, the semiconductor body 1111-1 may be at least partially surrounded by the gate structure 1111-2. For example, the semiconductor body 1111-1 and the gate structure 1111-2 may be arranged radially from the center of the vertical transistor in this order.

The arrangement in which the gate structure 1111-2 is disposed on a sidewall of the semiconductor body 1111-1, as illustrated in FIG. 7, is provided for illustrative purposes only and is not intended to be limiting. The gate structure 1111-2 may be formed on any suitable surface or region of the semiconductor body 1111-1, including but not limited to a sidewall, a top surface, a bottom surface, a recessed surface, or a combination thereof, depending on design requirements and fabrication considerations. Variations in placement or configuration of the gate structure are within the scope of the present disclosure.

In an implementation of the present disclosure, the gate structure 1111-2 may be located on sidewalls of the semiconductor body 1111-1, and the semiconductor body 1111-1 and the gate structure 1111-2 may be configured to jointly form a multi-gate transistor (e.g., a gate-all-around (GAA) transistor, a tri-gate transistor, or a double-gate transistor). A multi-gate transistor may have a larger gate control area to achieve better channel control with a smaller sub-threshold swing. During the off-state, the leakage current of the multi-gate transistor may also be significantly reduced since the channel is fully depleted. Thus, better speed (saturated drain current)/leakage current performance can be achieved using multi-gate transistors.

In another implementation of the present disclosure, the gate structure 1111-2 may be located on a sidewall of the semiconductor body 1111-1, and the semiconductor body 1111-1 and the gate structure 1111-2 may be configured to jointly form a single-gate transistor. For example, adjacent single-gate transistors in the first direction Z may be symmetrically arranged. In the present disclosure, by providing the single-gate transistor, the density of the semiconductor body 1111-1 in the first direction Z can be significantly increased, and the complexity of the manufacturing process may be reduced. In addition, the mirror-symmetric single-gate transistor may have a large process window, which is beneficial to reduce the spacing between the subsequently formed bit line 1113, word line and transistor, etc.

In an implementation, as shown in FIG. 7, the gate structure 1111-2 may be located on a side of the semiconductor body 1111-1 in the third direction Y. A dimension of the gate structure 1111-2 in the second direction X may be greater than a dimension of the gate structure 1111-2 in the third direction Y. For example, the gate structure 1111-2 may extend to a word line along the second direction X. As shown in FIG. 3, the bit line 1113 may be located at a side of the transistor 1111 (such as the semiconductor body 1111-1) in the first direction Z. A dimension of the bit line 1113 in the third direction Y may be greater than a dimension of the bit line 1113 in the second direction X. For example, the bit line 1113 may be connected to drains of a plurality of transistors 1111 arranged in the third direction Y (e.g., an end of the semiconductor body 1111-1 in the first direction Z). The capacitor 1112 may be located on the other side of the transistor 1111 (such as the semiconductor body 1111-1) in the first direction Z. The capacitor 1112 may be connected to the source of the transistor 1111 (e.g., the other end of the semiconductor body 1111-1 in the first direction Z).

The word line may be configured to control switching of the transistor 1111 in a row of memory cells in the second direction X. The bit line 1113 may be configured to send data to and/or receive data from memory cells in a column in the third direction Y. That is, each word line may be coupled to a corresponding row of memory cells and each bit line 1113 may be coupled to a corresponding column of memory cells. The voltage signal on the word line can control turning on or off of the transistor, thereby reading the data information stored in the capacitor 1112 through the bit line 1113, or writing the data information into the capacitor 1112 for storage through the bit line 1113. The capacitor 1112 may include a first electrode (not shown) connected to the transistor 1111, a capacitor dielectric layer (not shown) in contact with the first electrode, and a second electrode (not shown) in contact with the capacitor dielectric layer.

The capacitor 1112 may be implemented in any suitable configuration and is not limited to a particular capacitor architecture. By way of example and without limitation, the capacitor 1112 may include a planar capacitor, a stacked capacitor, a multi-fin capacitor, a cylindrical capacitor, a trench capacitor, a substrate-plate capacitor, or other capacitor structures now known or later developed. The capacitor 1112 may be formed above, within, or partially within a semiconductor substrate, and may extend in vertical, horizontal, or non-planar orientations. In certain illustrative embodiments, the capacitor 1112 may be configured as a vertical capacitor in which a first electrode, a capacitor dielectric layer, and a second electrode are arranged sequentially along the first direction Z. The capacitor dielectric layer may be disposed between the first electrode and the second electrode to provide charge storage capability. However, the relative orientation, stacking order, geometry, and structural configuration of the electrodes and dielectric layer may vary depending on design requirements and fabrication processes, and such variations are within the scope of the present disclosure.

In an implementation, as shown in FIG. 4, the second semiconductor structure 1200 may include two second portions spaced apart from each other in the second direction X, such as a second portion 1221 and a second portion 1222. The second portion 1221 and second portion 1222 may each be located between the first portion 1211 and first portion 1212. For example, both the second portion 1221 and the second portion 1222 may be located between two adjacent first portions (e.g., the first portion 1211 and the first portion 1212) in the third direction Y. The circuits in the first portion, such as the first portion 1211 and the first portion 1212, may include a sense amplifier circuit SA. The sense amplifier circuit SA may be connected with the bit line 1113. The circuits in the second portion such as the second portion 1221 and the second portion 1222 may include a word line driver circuit WLD. The word line driver circuit WLD may be connected to the gate structure 1111-2. The circuits in the third portion may include any suitable digital, analog, and/or mixed-signal circuit for facilitating operation of the memory cell array. For example, the circuits in the third portion may include one or more of page buffer circuits, decoding circuits (e.g., row decoding circuits and column decoding circuits), input/output circuits (e.g., data input/output buffers), charge pumps, voltage sources or generators, current or voltage references, any portions (e.g., sub-circuits) of the functional circuits described above, or any active or passive components of the circuits (e.g., peripheral transistors, diodes, resistors, or capacitors). For example, the circuits in the third portion may include, but are not limited to, at least one of a command buffer, a command decoder, an address buffer, a data buffer, a mode register, etc.

In an implementation, the memory block 1110 may include M bit lines 1113 and N word lines. The circuits (such as the sense amplifier circuit SA) in the first portion such as the first portion 1211 and the first portion 1212 may be configured to control the M bit lines 1113 in the corresponding memory block such as the memory block 1110. Circuits (such as the word line driver circuit WLD) in the second portion such as the second portion 1221 and the second portion 1222 may be configured to control N word lines in a corresponding memory block such as the memory block 1110. For example, the circuits (such as the sense amplifier circuit SA) in the first portion 1211 and the first portion 1212 may be connected to the M bit lines 1113 in the corresponding memory block 1110. The circuits (such as the word line driver circuit WLD) in the second portion such as the second portion 1221 and the second portion 1222 may be connected to the N word lines in the corresponding memory block 1110.

In an implementation, as shown in FIG. 4, a dimension of the first portion 1211 (and/or the first portion 1212) in the second direction X may be greater than its dimension in the third direction Y. For example, the first portion 1211 (and/or the first portion 1212) may extend along the second direction X to connect the sense amplifier circuit SA in the first portion 1211 (and/or the first portion 1212) with a plurality of bit lines 1113 spaced apart from each other in the second direction X. For example, a short conductive component (for example, perpendicular to the bit line 1113 and the first portion 1211 (and/or the first portion 1212)) may be configured to connect the sense amplifier circuit SA to the bit line 1113, to achieve better connection routing, thereby mitigating the coupling effect caused by long-distance routing between the sense amplifier circuit SA and the bit line 1113, and improving the sensing window.

In an implementation, as shown in FIG. 4, a dimension of the second portion 1221 (and/or the second portion 1222) in the third direction Y may be greater than its dimension in the second direction X. For example, the second portion 1221 (and/or the second portion 1222) may extend along the third direction Y to connect the word line driver circuit WLD in the second portion 1221 (and/or the second portion 1222) with a plurality of gate structures 1111-2 spaced apart from each other in the third direction Y. For example, a short conductive component (for example, perpendicular to the gate structure 1111-2 and the second portion 1221 (and/or the second portion 1222)) may be configured to connect the word line driver circuit WLD to the gate structure 1111-2, so as to achieve better connection routing, thereby improving the voltage drop caused by the long-distance routing of the word line driver circuit WLD and the word line.

In the present disclosure, the dimensions, proportions, and/or spatial arrangement of the first portion and the second portion are selected to facilitate electrical coupling between the sense amplifier circuit SA and the corresponding bit lines, as well as between the word line driver circuit WLD and the corresponding word lines. Such configuration may improve routing efficiency, reduce interconnect length, and optimize layout density. By reducing routing distance and associated parasitic resistance, capacitance, and signal delay, the disclosed arrangement may mitigate signal degradation, power consumption, and other adverse effects associated with extended interconnect paths. Variations in the dimensions and relative positioning of the first portion and the second portion that achieve similar routing or performance benefits are within the scope of the present disclosure.

In an implementation, as shown in FIG. 4, a dimension of the first portion 1211 (and/or the first portion 1212) in the second direction X may be the same as a dimension of the memory block 1110 in the second direction X. A dimension of the second portion 1221 (and/or the second portion 1222) in the third direction Y may be smaller than a dimension of the memory block 1110 in the third direction Y. Some edges of the first portion 1211, the first portion 1212, the second portion 1221, and the second portion 1222 may overlap with edges of the orthographic projection of the memory block 1110 in the first direction Z. In the present disclosure, the edges of the first portion and the second portion are configured to overlap with edges of the orthographic projection of the memory block 1110 in the first direction Z, which facilitates a more concentrated space occupied by the third portion (the remaining space of the orthographic projection of the memory block 1110 in the first direction Z), and mitigates the scattered distribution of circuits in the third portion, so as to reduce the layout difficulty of circuits in the third portion.

As used herein, the term “the same dimension” refers to a nominal dimension established during the design stage of the product or process. It is recognized that, due to inherent manufacturing variations and process limitations, the actual dimension obtained during fabrication may deviate from the nominal design value. Such deviations, including but not limited to variations arising from process tolerances, material properties, lithography limitations, etching or deposition inconsistencies, are considered within the scope of the present disclosure. In certain embodiments, the deviation may be within a range of approximately 10% to 30% of the nominal dimension, including, for example, ±10%, ±20%, or ±30%. The term “the same dimension” is intended to encompass both the nominal design value and any such permissible deviations.

In an implementation, as shown in FIG. 4, a dimension of the first portion 1211 (and/or the first portion 1212) in the second direction X may be the same as a dimension of the third portion 1230 in the second direction X. A part of the third portion 1230 may be located on at least a side of the second portion 1221 (and/or the second portion 1222) in the third direction Y. The remaining part of the third portion 1230 may be located between the second portion 1221 and the second portion 1222. For example, the third portion 1230 may be located in a region of the orthographic projection region of one memory block 1110 in the first direction Z excluding the first portion and the second portion.

In an implementation, as shown in FIG. 4, the first portion 1211 (and/or the first portion 1212) may include a first end 1210-1 and a second end 1210-2 opposite to each other in the second direction X. A dimension of the first end 1210-1 in the third direction Y may be different from a dimension of the second end 1210-2 in the third direction Y, so as to provide a number of sense amplifier circuits SA in the first portion which can meet actual requirements.

It should be noted that the dimensions of the first end 1210-1 and the second end 1210-2 in the present disclosure are only examples and are not specifically limited. In an actual process, the dimensions of the first end 1210-1 and the second end 1210-2 may be properly set according to the number of the sense amplifier circuits SA in the first portion and the arrangement of the bit lines.

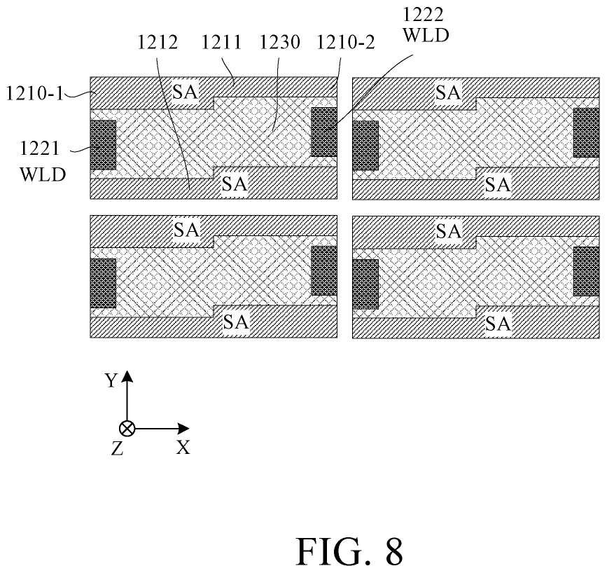

FIG. 8 is a schematic arrangement diagram of a first portion, a second portion, and a third portion corresponding to four memory blocks arranged in an array in a second direction X and a third direction Y, according to some embodiments of the present disclosure.

As shown in FIG. 8, the arrangement of the first portion (such as the first portion 1211 and the first portion 1212), the second portion (such as the second portion 1221 and the second portion 1222), and the third portion 1230 corresponding to the four memory blocks may be the same or symmetrical. For example, the arrangements of the circuits in the first portion such as the sense amplifier circuit SA, the circuits in the second portion such as the word line driver circuit WLD, and the third portion corresponding to the four memory blocks may be the same or symmetrical.

It should be noted that “corresponding to the memory block” referred to in the present disclosure may be construed approximately as “overlapping with the projection of the memory block in the first direction Z”.

In an implementation, as shown in FIG. 3, the semiconductor device 1000 may further include a first interconnect layer 1300, a second interconnect layer 1400, and a conductive structure 1500. The first interconnect layer 1300 may be located between the first semiconductor structure 1100 and the second semiconductor structure 1200. The second interconnect layer 1400 may be located on a side of the second semiconductor structure 1200 facing away from the first semiconductor structure 1100. The conductive structure 1500 may extend through the second semiconductor structure 1200 in the first direction Z, and may be connected to the first interconnect layer 1300 and the second interconnect layer 1400. For example, the first interconnect layer 1300 may be connected to a circuit in the third portion 1230. For example, the circuit in the third portion 1230 may be connected to the second interconnect layer 1400 via the first interconnect layer 1300 and the conductive structures 1500.

In an implementation, as shown in FIG. 3, both the first interconnect layer 1300 and the second interconnect layer 1400 may include a plurality of metal layers (configured to form interconnect lines) spaced apart from each other in the first direction Z in the dielectric layer and an interconnect structure connecting the multilayer interconnect lines.

The interconnect lines and interconnect structures in the first interconnect layer 1300 and the second interconnect layer 1400 may include conductive materials, including but not limited to, tungsten, copper, aluminum, doped silicon, silicides, or any combination thereof. The dielectric layer may be formed of a dielectric material including, but not limited to, silicon oxide, silicon nitride, silicon oxynitride, a low dielectric constant material layer, or any combination thereof.

As shown in FIG. 3, the conductive structure 1500 may extend through the isolation structure 1240 (configured to separate adjacent circuits) in the second semiconductor structure 1200 in the first direction Z. In the present disclosure, by providing the conductive structure 1500, the routing process of wirings between the first interconnect layer 1300 and the second interconnect layer 1400 is simplified, and the routing difficulty is reduced. In an implementation, the conductive structure 1500 may include a conductive material, such as including but not limited to tungsten, copper, aluminum, doped silicon, silicide, or any combination thereof. The isolation structure 1240 may include an insulating material, for example, including but not limited to silicon oxide or silicon nitride.

In an implementation, as shown in FIG. 3, the semiconductor device 1000 may further include a power line (not shown) and a pad structure 1600. The power line may be located on a side of the second interconnect layer 1400 facing away from the second semiconductor structure 1200. The pad structure 1600 may be located on a side of the power line facing away from the second interconnect layer 1400. In other words, the power line may be located between the second interconnect layer 1400 and the pad structure 1600. The pad structure 1600 may route electrical signals between the semiconductor device and an external circuit.

In the present disclosure, the power line is provided on the side of the second interconnect layer 1400 facing away from the second semiconductor structure 1200, which facilitates shortening the length of the interconnect structure between the second semiconductor structure 1200 and the power line, thereby reducing the parasitic capacitance of the interconnect structure and improving the sensing tolerance and storage density of the semiconductor device.

In an implementation, as shown in FIG. 3, the semiconductor device 1000 may further include a substrate 1700. The substrate 1700 may be located on a side of the first semiconductor structure 1100 facing away from the second semiconductor structure 1200 in the first direction Z to carry the first semiconductor structure 1100.

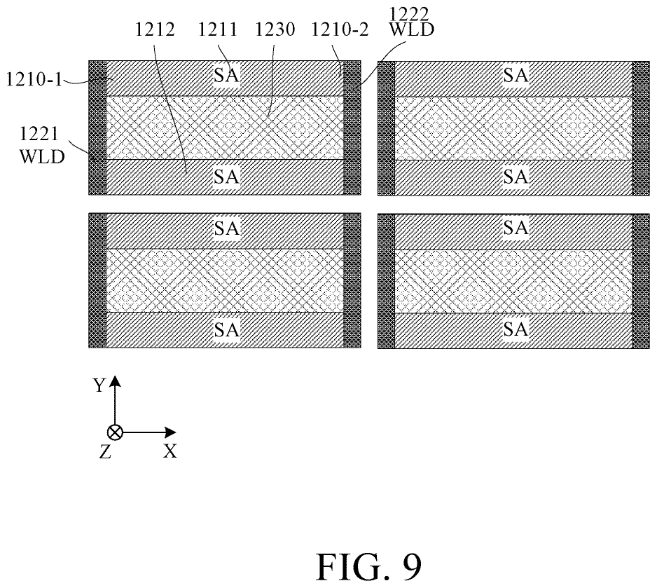

FIG. 9 is a schematic arrangement diagram of a first portion, a second portion, and a third portion corresponding to four memory blocks arranged in an array in a second direction X and a third direction Y according to another implementation of the present disclosure. In this implementation, for the sake of brevity, some descriptions similar to those in the implementations shown in FIGS. 1 to 8 will be omitted.

As shown in FIG. 9, the second semiconductor structure 1200 may include two second portions spaced apart from each other in the second direction X, such as a second portion 1221 and a second portion 1222. The second portion 1221 and the second portion 1222 may be located on two sides of the first portion 1211 (or the first portion 1212) and the third portion 1230 in the second direction X, respectively. For example, the second portion 1221 may be located at an end of the first portion 1211 and the first portion 1212 in the second direction X, and the second portion 1222 may be located at the other end of the first portion 1211 and the first portion 1212 in the second direction X. A dimension of the second portion 1221 (and/or the second portion 1222) in the third direction Y may be the same as a dimension of the memory block 1110 in the third direction Y. A dimension of the first portion 1211 (and/or the first portion 1212) in the second direction X may be smaller than a dimension of the memory block 1110 in the second direction X. Some edges of the first portion 1211, the first portion 1212, the second portion 1221, and the second portion 1222 may overlap with edges of the orthographic projection of the memory block 1110 in the first direction Z. In the present disclosure, some edges of the first portion and the second portion are configured to overlap with edges of the orthographic projection of the memory block 1110 in the first direction Z, which facilitates a more concentrated space occupied by the third portion (the remaining space of the orthographic projection of the memory block 1110 in the first direction Z), and mitigates the scattered distribution of circuits in the third portion, so as to reduce the layout difficulty of circuits in the third portion.

In an implementation, as shown in FIG. 9, the third portion 1230 is located between the first portion 1211 and the first portion 1212. A dimension of the first portion 1211 (and/or the first portion 1212) in the second direction X may be the same as a dimension of the third portion 1230 in the second direction X.

In an implementation, as shown in FIG. 9, the first portion 1211 (and/or the first portion 1212) may include a first end 1210-1 and a second end 1210-2 opposite to each other in the second direction X. A dimension of the first end 1210-1 in the third direction Y may be the same as a dimension of the second end 1210-2 in the third direction Y, so as to provide a number of sense amplifier circuits SA in the first portion which can meet actual requirements.

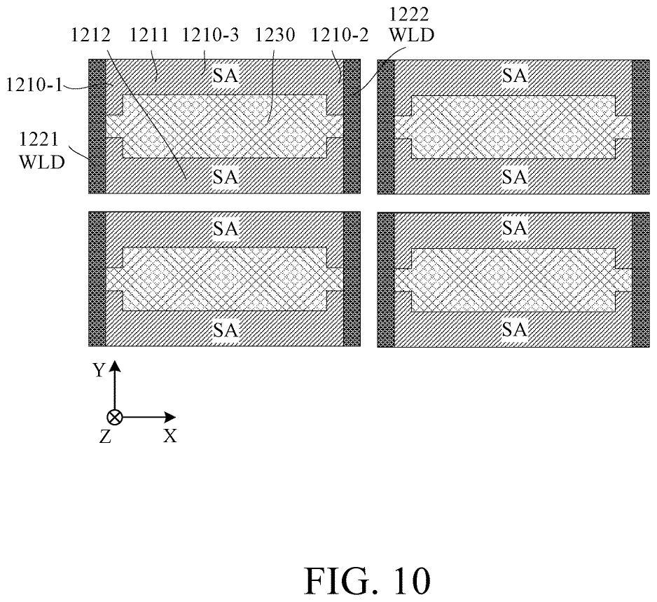

FIG. 10 is a schematic arrangement diagram of a first portion, a second portion, and a third portion corresponding to four memory blocks arranged in an array in a second direction X and a third direction Y according to another implementation of the present disclosure. In this implementation, for the sake of brevity, some descriptions similar to those in the implementations shown in FIG. 9 will be omitted.

In an implementation, as shown in FIG. 10, the first portion 1211 (and/or the first portion 1212) may include a first end 1210-1 and a second end 1210-2 opposite to each other in the second direction X, and an intermediate portion 1210-3 located between the first end 1210-1 and the second end 1210-2. A dimension of the first end 1210-1 in the third direction Y may be greater than a dimension of the intermediate portion 1210-3 in the third direction Y, so as to provide a number of sense amplifier circuits SA in the first portion which can meet actual requirements. A dimension of the first end 1210-1 in the third direction Y may be the same as a dimension of the second end 1210-2 in the third direction Y.

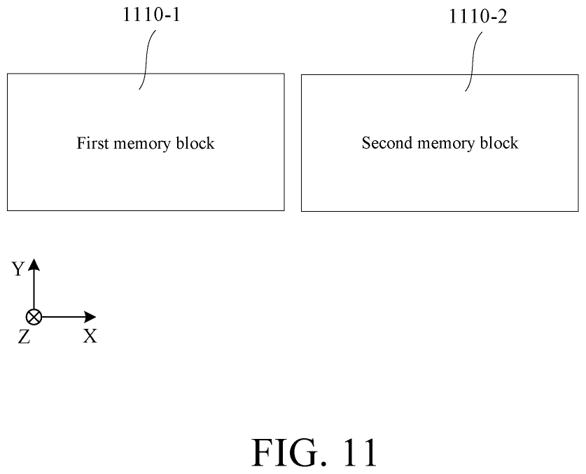

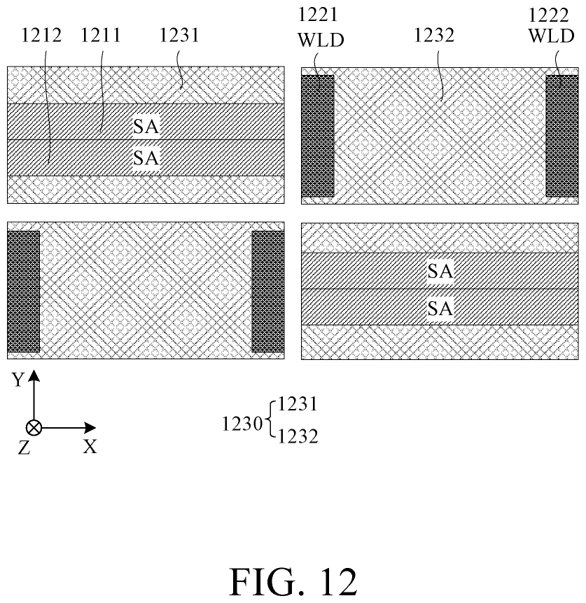

FIG. 11 is an enlarged view of area C in FIG. 6. FIG. 12 is a schematic arrangement diagram of a first portion, a second portion, and a third portion corresponding to four memory blocks arranged in an array in a second direction X and a third direction Y according to another implementation of the present disclosure. In this implementation, for the sake of brevity, some descriptions similar to those in the implementations shown in FIGS. 1 to 8 will be omitted.

Referring to FIGS. 5 and 6, a memory bank (e.g., memory bank 0) in the first semiconductor structure 1100 may include a plurality of memory blocks 1110. As shown in FIG. 11, the plurality of memory blocks 1110 may include a first memory block 1110-1 and a second memory block 1110-2 that are adjacent to each other. The first memory block 1110-1 and the second memory block 1110-2 may be adjacent in the second direction X.

It should be understood that the first memory block 1110-1 and the second memory block 1110-2 may also be adjacent in the third direction Y. The first memory block 1110-1 and the second memory block 1110-2 may be spaced apart. The first memory block 1110-1 and the second memory block 1110-2 may each include memory cells, word lines, and bit lines 1113 (see FIG. 3).

In an implementation, as shown in FIGS. 11 and 12, the first portion 1211 and the first portion 1212 in the second semiconductor structure 1200 may be located on a side of the first memory block 1110-1 in the first direction Z. The second portion 1221 and the second portion 1222 in the second semiconductor structure 1200 may be located on a side of the second memory block 1110-2 in the first direction Z. The third portion 1230 may include a first sub-portion 1231 and a second sub-portion 1232. The first sub-portion 1231 may be located on a side of the first memory block 1110-1 in the first direction Z. The second sub-portion 1232 may be located on a side of the second memory block 1110-2 in the first direction Z. The first portion 1211 (and the first portion 1212), the second portion 1221 (and the second portion 1222), and the third portion 1230 may include different circuits. In other words, the two first portions and the first sub-portion 1231 of the third portion 1230 may both be located on a side of the first memory block 1110-1 in the first direction Z. The two second portions and the second sub-portion 1232 in the third portion 1230 may both be located on a side of the second memory block 1110-2 in the first direction Z.

It should be noted that the circuits (such as the sense amplifier circuit SA) in the first portion 1211 and the first portion 1212 may be configured to control the bit lines in the first memory block 1110-1 and the second memory block 1110-2. The circuits (such as the word line driver circuit WLD) in the second portion 1221 and the second portion 1222 may be configured to control word lines in the first memory block 1110-1 and the second memory block 1110-2.

For example, the first memory block 1110-1 may include M1 bit lines and N1 word lines, and the second memory block 1110-2 may include M2 bit lines and N2 word lines. The circuits (such as the sense amplifier circuit SA) in the first portion 1211 and the first portion 1212 may be connected to M1+M2 bit lines in the first memory block 1110-1 and the second memory block 1110-2. The circuits (such as the word line driver circuit WLD) in the second portion 1221 and the second portion 1222 may be connected to N1+N2 word lines in the first memory block 1110-1 and the second memory block 1110-2.

In the present disclosure, the first portion, the second portion, and the third portion are arranged on a side of the first memory block 1110-1 and the second memory block 1110-2 in the first direction Z, which facilitates a suitable layout of the arrangement positions of the first portion, the second portion, and the third portion, and a reduction of the overall dimension of the second semiconductor structure 1200, thereby improving the overall performance of the semiconductor device.

In addition, the two first portions and the first sub-portion 1231 are both arranged on a side of the first memory block 1110-1 in the first direction Z, and the two second portions and the second sub-portion 1232 are both arranged on a side of the second memory block 1110-2 in the first direction Z, which facilitates a more concentrated space occupied by the third portion on the basis that the first portion, the second portion and the third portion are located on a side of the first memory block 1110-1 and the second memory block 1110-2 in the first direction Z, and mitigates the scattered distribution of circuits in the third portion, so as to reduce the layout difficulty of circuits in the third portion. For example, as shown in FIG. 12, the space occupied by the first sub-portion 1231 and the second sub-portion 1232 is relatively concentrated.

In an implementation, as shown in FIG. 12, the two first portions and the first sub-portion 1231 may overlap with the projection of the first memory block 1110-1 in the first direction Z. In other words, the two first portions and the first sub-portion 1231 may be located directly below or directly above the first memory block 1110-1 in the first direction Z. The two second portions and the second sub-portion 1232 may overlap with the projection of the second memory block 1110-2 in the first direction Z. In other words, the two second portions and the second sub-portion 1232 may be located directly below or directly above the second memory block 1110-2 in the first direction Z.

The first portion 1211 and the first portion 1212 may be adjacent in the third direction Y. The first sub-portion 1231 may be located on two sides of the first portion 1211 and the first portion 1212 in the third direction Y. A dimension of the first portion 1211 (and/or the first portion 1212) in the second direction X may be the same as a dimension of the first memory block 1110-1 in the second direction X. A dimension of the first sub-portion 1231 in the second direction X may be the same as a dimension of the first portion 1211 in the second direction X. Some edges of the two first portions and the first sub-portion 1231 may overlap with edges of the orthographic projection of the first memory block 1110-1 in the first direction Z.

The second portion 1221 and the second portion 1222 may be spaced apart in the second direction X. A dimension of the second portion 1221 (and/or the second portion 1222) in the third direction Y may be less than or equal to a dimension of the second memory block 1110-2 in the third direction Y. A part of the second sub-portion 1232 may be located on at least a side of the second portion 1221 and the second portion 1222 in the third direction Y. The remaining part of the second sub-portion 1232 may be located between the second portion 1221 and the second portion 1222. Some edges of the two second portions and the second sub-portion 1232 may overlap with edges of the orthographic projection of the second memory block 1110-2 in the first direction Z.

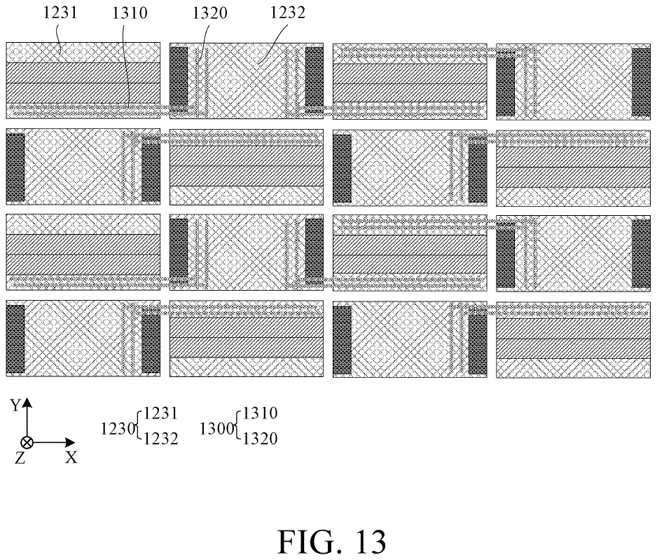

FIG. 13 is a schematic diagram of circuit routings in the first interconnect layer 1300 and the third portion 1230, according to some embodiments of the present disclosure. As shown in FIG. 13, the first interconnect layer 1300 may include a multilayer of interconnect lines spaced apart from each other in the first direction Z, such as an interconnect line 1310 and an interconnect line 1320. In the present disclosure, circuits in the first sub-portion 1231 and the second sub-portion 1232 may be connected by providing the multilayer of the interconnect line 1310 and the interconnect line 1320.

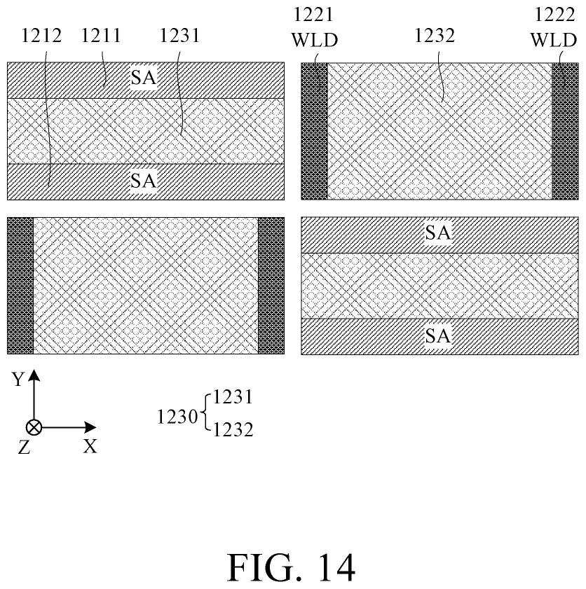

FIG. 14 is a schematic arrangement diagram of a first portion, a second portion, and a third portion corresponding to four memory blocks arranged in an array in a second direction X and a third direction Y according to another implementation of the present disclosure. In this implementation, for the sake of brevity, some descriptions similar to those in the implementations shown in FIGS. 11 to 13 will be omitted.

As shown in FIGS. 11 and 14, the first portion 1211, the first portion 1212, and the first sub-portion 1231 may all be located on a side of the first memory block 1110-1 in the first direction Z. The second portion 1221, the second portion 1222, and the second sub-portion 1232 may all be located on a side of the second memory block 1110-2 in the first direction Z.

The first portion 1211 and the first portion 1212 may be spaced apart in the third direction Y. The first sub-portion 1231 may be located between the first portion 1211 and the first portion 1212. A dimension of the first portion 1211 (and/or the first portion 1212) in the second direction X may be the same as a dimension of the first memory block 1110-1 in the second direction X. A dimension of the first sub-portion 1231 in the second direction X may be the same as a dimension of the first portion 1211 (and/or the first portion 1212) in the second direction X. Some edges of the first portion 1211, the first portion 1212, and the first sub-portion 1231 may overlap with edges of the orthographic projection of the first memory block 1110-1 in the first direction Z.

The second portion 1221 and the second portion 1222 may be spaced apart in the second direction X. The second sub-portion 1232 may be located between the second portion 1221 and the second portion 1222. A dimension of the second portion 1221 (and/or the second portion 1222) in the third direction Y is the same as a dimension of the second memory block 1110-2 in the third direction Y. Some edges of the two second portions and the second sub-portion 1232 may overlap with edges of the orthographic projection of the second memory block 1110-2 in the first direction Z.

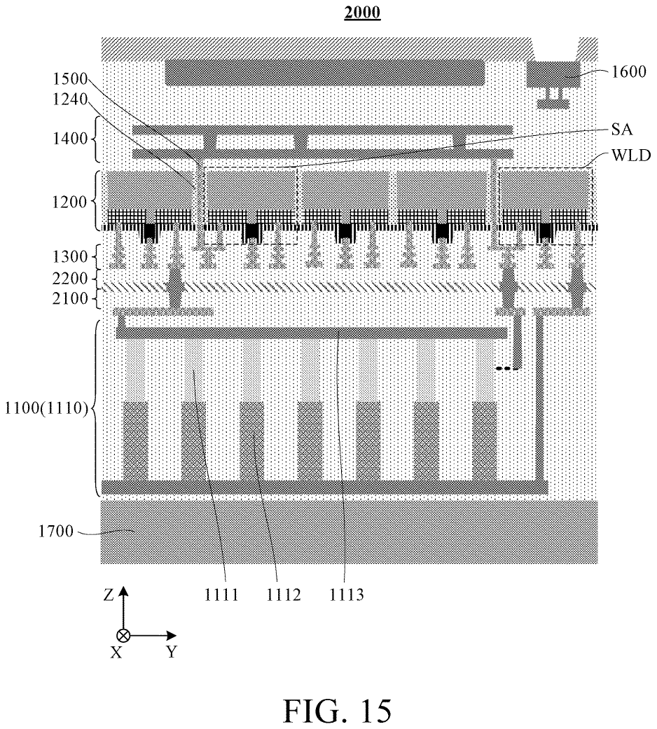

FIG. 15 is a schematic structural diagram of a semiconductor device 2000 according to another implementation of the present disclosure. In this implementation, for the sake of brevity, some descriptions similar to those in the implementations shown in FIGS. 1 to 14 will be omitted.

The semiconductor device 2000 may further include a first bonding layer 2100 and a second bonding layer 2200 connected together. The first bonding layer 2100 may be located on a side of the first semiconductor structure 1100 facing away from the substrate 1700. The second bonding layer 2200 may be located on a side of the first interconnect layer 1300 facing away from the second semiconductor structure 1200. The first semiconductor structure 1100 and the second semiconductor structure 1200 may be connected by a first bonding layer 2100 and a second bonding layer 2200.

The first bonding layer 2100 and the second bonding layer 2200 may each include a bonding structure and a dielectric that isolates the bonding structure. The bonding structure may include a conductive material, including, but not limited to, tungsten, copper, aluminum, doped silicon, silicide, or any combination thereof. The dielectric may be formed of a dielectric material including, but not limited to, silicon oxide, silicon nitride, silicon oxynitride, a low dielectric constant material layer, or any combination thereof.

It should be noted that both the first semiconductor structure 1100 and the second semiconductor structure 1200 in this implementation may be similar to the first semiconductor structure 1100 and the second semiconductor structure 1200 shown in FIG. 3. The arrangements of the first portion, the second portion and the third portion in the second semiconductor structure 1200 shown in FIGS. 8 to 14 are all applicable to this implementation.

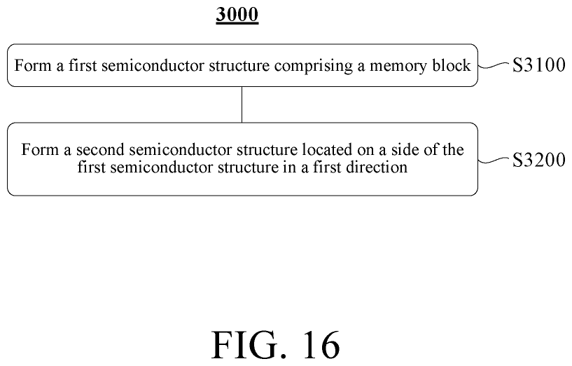

FIG. 16 is a flowchart of a method 3000 of manufacturing a semiconductor device, according to some embodiments of the present disclosure.

As shown in FIG. 16, the method 3000 of manufacturing the semiconductor device may include: at operation S3100, forming a first semiconductor structure, the first semiconductor structure comprising a memory block; and at operation S3200, forming a second semiconductor structure, the second semiconductor structure being located on a side of the first semiconductor structure in a first direction. Operations S3100 and S3200 will be described in detail below.

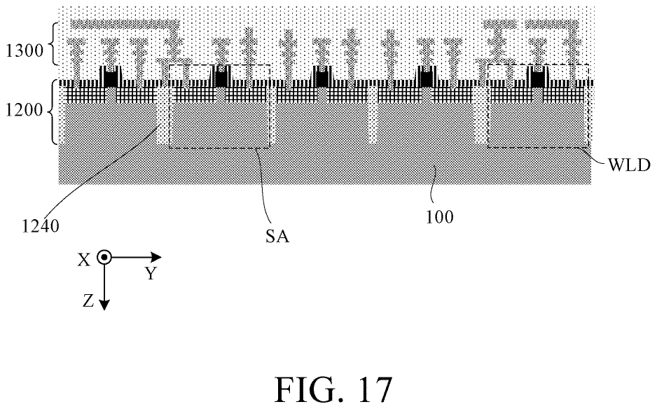

FIG. 17 is a schematic structural diagram after formation of a second semiconductor structure 1200 and a first interconnect layer 1300, according to some embodiments of the present disclosure.

In an implementation, the second semiconductor structure 1200 may be formed on a side of the semiconductor layer 100. The semiconductor layer 100 can include at least one of monocrystalline silicon, polycrystalline silicon, monocrystalline germanium, a III-V compound semiconductor material, a II-VI compound semiconductor material, or other semiconductor materials known in the art.

Forming the second semiconductor structure 1200 may include: forming a plurality of well regions (such as a P-type well region and an N-type well region) in the semiconductor layer 100 and an isolation structure 1240 separating the plurality of well regions; doping the plurality of well regions (such as N-type doping in the P-type well region and P-type doping in the N-type well region) to form a plurality of doped regions; and forming a gate between the doped regions on a side of the semiconductor layer 100 to form a plurality of circuits (such as peripheral transistors).

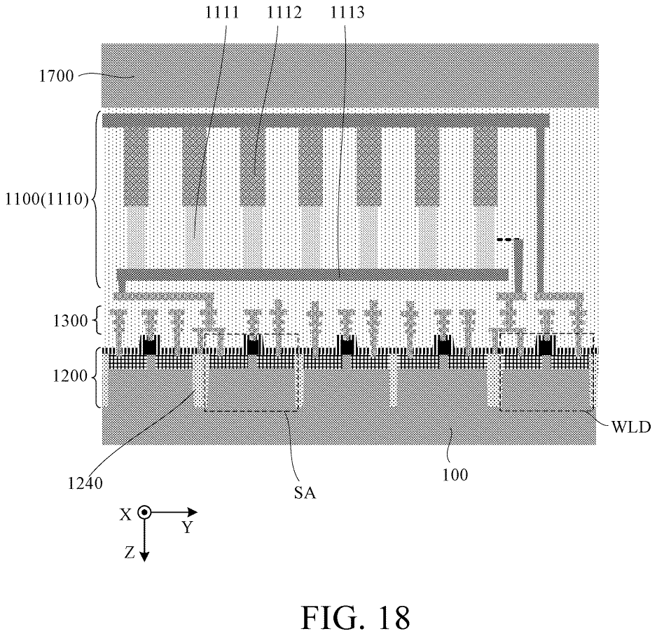

Referring to FIGS. 8 to 10, the second semiconductor structure 1200 may include a plurality of regions arranged in an array in the second direction X and the third direction Y. Each region may correspond to a subsequently formed memory block 1110 (see FIG. 18, which will be described in detail below). For example, each region may be located on a side of the memory block 1110 in the first direction Z. One memory block 1110 may overlap a projection of one region in the first direction Z. One region may include two first portions (such as the first portion 1211 and first portion 1212), two second portions (such as the second portion 1221 and second portion 1222), and the third portion 1230.

The first portion 1211 (and the first portion 1212), the second portion 1221 (or the second portion 1222), and the third portion 1230 may include different circuits. For example, the circuits in the first portion, such as the first portion 1211 and first portion 1212, may include a sense amplifier circuit SA. The sense amplifier circuit SA may be connected to a bit line 1113 (see FIG. 18, which will be described in detail below). The circuits in the second portion, such as the second portion 1221 and the second portion 1222, may include a word line driver circuit WLD. The word line driver circuit WLD may be connected to the gate structure 1111-2 (referring to FIG. 7, which will be described in detail below). The circuits in the third portion may include any suitable digital, analog, and/or mixed-signal circuit for facilitating operation of the memory cell array. For example, the circuits in the third portion may include one or more of page buffer circuits, decoding circuits (e.g., row decoding circuits and column decoding circuits), input/output circuits (e.g., data input/output buffers), charge pumps, voltage sources or generators, current or voltage references, any portions (e.g., sub-circuits) of the functional circuits described above, or any active or passive components of the circuits (e.g., peripheral transistors, diodes, resistors, or capacitors). For example, the circuits in the third portion may include, but are not limited to, at least one of a command buffer, a command decoder, an address buffer, a data buffer, a mode register, etc.

In an implementation of the present disclosure, referring to FIG. 8, the first portion 1211 and the first portion 1212 may be spaced apart from each other in the third direction Y. The second portion 1221 and the second portion 1222 may be located on a side of the first portion 1211 (or the first portion 1212) in the third direction Y. The third portion 1230 may be located between the first portion 1211 and the first portion 1212.

In the present disclosure, the first portion, the second portion, and the third portion are all arranged on a side of the memory block 1110 in the first direction Z, which facilitates a suitable layout of the arrangement positions of the first portion, the second portion, and the third portion, and a reduction of the overall dimension of the second semiconductor structure 1200, thereby improving the overall performance of the semiconductor device.

In addition, the two first portions are spaced apart from each other in the third direction Y, and the second portion is located on a side of the first portion in the third direction Y, which facilitates a more concentrated space occupied by the third portion on the basis that the first portion, the second portion, and the third portion are all located on a side of the memory block 1110 in the first direction Z, thereby reducing the layout difficulty of circuits in the third portion.

In another implementation of the present disclosure, referring to FIG. 9, the second portion 1221 and the second portion 1222 may be located on two sides of the first portion 1211 (or the first portion 1212) and the third portion 1230 in the second direction X, respectively. A dimension of the second portion 1221 (and/or the second portion 1222) in the third direction Y may be the same as a dimension of the memory block 1110 in the third direction Y. A dimension of the first portion 1211 (and/or the first portion 1212) in the second direction X may be smaller than a dimension of the memory block 1110 in the second direction X. Some edges of the first portion 1211, the first portion 1212, the second portion 1221, and the second portion 1222 may overlap with edges of the orthographic projection of the memory block 1110 in the first direction Z. In the present disclosure, some edges of the first portion and the second portion are configured to overlap with edges of the orthographic projection of the memory block 1110 in the first direction Z, which facilitates a more concentrated space occupied by the third portion (the remaining space of the orthographic projection of the memory block 1110 in the first direction Z), and mitigates the scattered distribution of circuits in the third portion, so as to reduce the layout difficulty of circuits in the third portion.

The third portion 1230 is located between the first portion 1211 and the first portion 1212. A dimension of the first portion 1211 (and/or the first portion 1212) in the second direction X may be the same as a dimension of the third portion 1230 in the second direction X. The first portion 1211 (and/or the first portion 1212) may include a first end 1210-1 and a second end 1210-2 opposite in the second direction X. A dimension of the first end 1210-1 in the third direction Y may be the same as a dimension of the second end 1210-2 in the third direction Y, so as to provide a number of sense amplifier circuits SA in the first portion which can meet actual requirements.

In another implementation of the present disclosure, referring to FIG. 10, the first portion 1211 (and/or the first portion 1212) may include a first end 1210-1 and a second end 1210-2 opposite to each other in the second direction X, and an intermediate portion 1210-3 located between the first end 1210-1 and the second end 1210-2. A dimension of the first end 1210-1 in the third direction Y may be greater than a dimension of the intermediate portion 1210-3 in the third direction Y, so as to provide a desirable number of sense amplifier circuits SA in the first portion. A dimension of the first end 1210-1 in the third direction Y may be the same as a dimension of the second end 1210-2 in the third direction Y.

In another implementation of the present disclosure, referring to FIGS. 11 and 12, the plurality of memory blocks 1110 may include a first memory block 1110-1 and a second memory block 1110-2 adjacent to each other. The first memory block 1110-1 and the second memory block 1110-2 may be adjacent in the second direction X. It should be understood that the first memory block 1110-1 and the second memory block 1110-2 may also be adjacent in the third direction Y.

The first portion 1211 and the first portion 1212 in the second semiconductor structure 1200 may be located on a side of the first memory block 1110-1 in the first direction Z. The second portion 1221 and the second portion 1222 in the second semiconductor structure 1200 may be located on a side of the second memory block 1110-2 in the first direction Z. The third portion 1230 may include a first sub-portion 1231 and a second sub-portion 1232. The first sub-portion 1231 may be located on a side of the first memory block 1110-1 in the first direction Z. The second sub-portion 1232 may be located on a side of the second memory block 1110-2 in the first direction Z. The first portion 1211 (and the first portion 1212), the second portion 1221 (and the second portion 1222), and the third portion 1230 may include different circuits. In other words, the two first portions and the first sub-portion 1231 of the third portion 1230 may both be located on a side of the first memory block 1110-1 in the first direction Z. The two second portions and the second sub-portion 1232 in the third portion 1230 may both be located on a side of the second memory block 1110-2 in the first direction Z.

In the present disclosure, the first portion, the second portion, and the third portion are arranged on a side of the first memory block 1110-1 and the second memory block 1110-2 in the first direction Z, which facilitates a suitable layout of the arrangement positions of the first portion, the second portion, and the third portion, and a reduction of the overall dimension of the second semiconductor structure 1200, thereby improving the overall performance of the semiconductor device.

In addition, the two first portions and the first sub-portion 1231 are both arranged on a side of the first memory block 1110-1 in the first direction Z, and the two second portions and the second sub-portion 1232 are both arranged on a side of the second memory block 1110-2 in the first direction Z, which facilitates a more concentrated space occupied by the third portion on the basis that the first portion, the second portion and the third portion are located on a side of the first memory block 1110-1 and the second memory block 1110-2 in the first direction Z, and mitigates the scattered distribution of circuits in the third portion, so as to reduce the layout difficulty of circuits in the third portion. For example, as shown in FIG. 12, the space occupied by the first sub-portion 1231 and the second sub-portion 1232 is relatively concentrated.

In an implementation, as shown in FIG. 12, the two first portions and the first sub-portion 1231 may overlap with the projection of the first memory block 1110-1 in the first direction Z. In other words, the two first portions and the first sub-portion 1231 may be located directly below or directly above the first memory block 1110-1 in the first direction Z. The two second portions and the second sub-portion 1232 may overlap with the projection of the second memory block 1110-2 in the first direction Z. In other words, the two second portions and the second sub-portion 1232 may be located directly below or directly above the second memory block 1110-2 in the first direction Z.

The first portion 1211 and the first portion 1212 may be adjacent in the third direction Y. The first sub-portion 1231 may be located on two sides of the first portion 1211 and the first portion 1212 in the third direction Y. A dimension of the first portion 1211 (and/or the first portion 1212) in the second direction X may be the same as a dimension of the first memory block 1110-1 in the second direction X. A dimension of the first sub-portion 1231 in the second direction X may be the same as a dimension of the first portion 1211 in the second direction X. Some edges of the two first portions and the first sub-portion 1231 may overlap with edges of the orthographic projection of the first memory block 1110-1 in the first direction Z.

The second portion 1221 and the second portion 1222 may be spaced apart in the second direction X. A dimension of the second portion 1221 (and/or the second portion 1222) in the third direction Y may be less than or equal to a dimension of the second memory block 1110-2 in the third direction Y. A part of the second sub-portion 1232 may be located on at least a side of the second portion 1221 and the second portion 1222 in the third direction Y. The remaining part of the second sub-portion 1232 may be located between the second portion 1221 and the second portion 1222. Some edges of the two second portions and the second sub-portion 1232 may overlap with edges of the orthographic projection of the second memory block 1110-2 in the first direction Z.

In another implementation of the present disclosure, referring to FIGS. 11 and 14, the first portion 1211, the first portion 1212, and the first sub-portion 1231 may all be located on a side of the first memory block 1110-1 in the first direction Z. The second portion 1221, the second portion 1222, and the second sub-portion 1232 may all be located on a side of the second memory block 1110-2 in the first direction Z.

The first portion 1211 and the first portion 1212 may be spaced apart in the third direction Y. The first sub-portion 1231 may be located between the first portion 1211 and the first portion 1212. A dimension of the first portion 1211 (and/or the first portion 1212) in the second direction X may be the same as a dimension of the first memory block 1110-1 in the second direction X. A dimension of the first sub-portion 1231 in the second direction X may be the same as a dimension of the first portion 1211 (and/or the first portion 1212) in the second direction X. Some edges of the first portion 1211, the first portion 1212, and the first sub-portion 1231 may overlap with edges of the orthographic projection of the first memory block 1110-1 in the first direction Z.

The second portion 1221 and the second portion 1222 may be spaced apart in the second direction X. The second sub-portion 1232 may be located between the second portion 1221 and the second portion 1222. A dimension of the second portion 1221 (and/or the second portion 1222) in the third direction Y is the same as a dimension of the second memory block 1110-2 in the third direction Y. Some edges of the two second portions and the second sub-portion 1232 may overlap with edges of the orthographic projection of the second memory block 1110-2 in the first direction Z.

In an implementation, as shown in FIG. 17, a first interconnect layer 1300 may be formed on a side of the second semiconductor structure 1200 in the first direction Z. The first interconnect layer 1300 may connect circuits in the third portion 1230. For example, the first interconnect layer 1300 may be formed by one or more thin film deposition processes and one or more etching processes.

The first interconnect layer 1300 may include a plurality of metal layers (for forming interconnect lines, such as an interconnect line 1310 and an interconnect line 1320 shown in FIG. 13) spaced apart from each other in the first direction Z in the dielectric layer and an interconnect structure connecting the multilayer interconnect lines. The multilayer interconnect lines and interconnect structures may connect the circuits in the third portion 1230.

The interconnect lines and interconnect structures within the first interconnect layer 1300 may be formed of any suitable conductive material, including, without limitation, tungsten, copper, aluminum, doped silicon, silicide, or any combination thereof. The dielectric layer may comprise any suitable dielectric material, including, without limitation, silicon oxide, silicon nitride, silicon oxynitride, a low-k dielectric material, or any combination thereof. Materials now known or later developed that provide equivalent electrical, mechanical, or thermal performance are also encompassed within the scope of the present disclosure.

FIG. 18 is a schematic structural diagram after formation of a first semiconductor structure 1100 and a substrate 1700, according to some embodiments of the present disclosure. In an implementation, the first semiconductor structure 1100 may be formed on a side of the first interconnect layer 1300 in the first direction Z. For example, the first semiconductor structure 1100 may be formed on a side of the first interconnect layer 1300 facing away from the second semiconductor structure 1200.

Forming the first semiconductor structure 1100 may include: forming a semiconductor body 1111-1; forming a gate structure 1111-2, where the gate structure 1111-2 is located on a side of the semiconductor body 1111-1 in the third direction Y; and forming a bit line 1113, where the bit line 1113 may be located on a side of the semiconductor body 1111-1 in the first direction Z.

As shown in FIG. 5, the first semiconductor structure 1100 may include a memory cell array, where the memory cell array may include a plurality of memory banks. For example, as shown in FIG. 5, the memory cell array may include eight memory banks such as memory bank 0, memory bank 1, memory bank 2, memory bank 3, memory bank 4, memory bank 5, memory bank 6, and memory bank 7. Each memory bank may include a plurality of memory blocks. For example, as shown in FIG. 6, memory bank 0 may include a plurality of memory blocks 1110. The plurality of memory blocks 1110 may be arranged in an array in the second direction X and the third direction Y.

The number of memory banks illustrated in the present disclosure is provided for illustrative purposes only and is not intended to be limiting. The semiconductor device may include any suitable number of memory banks, and the quantity, arrangement, and configuration of the memory banks may be selected or adjusted based on design requirements, performance considerations, fabrication constraints, or other implementation-specific factors. Variations in the number or organization of memory banks are fully encompassed within the scope of the present disclosure.

For example, the two first portions, the second portion, and the third portion may be located on a side of one memory block 1110 in the first direction Z. For example, the two first portions, the second portion and the third portion may overlap with the projection of one memory block 1110 in the first direction Z. In other words, the two first portions, the second portion and the third portion may be located directly below or directly above one memory block 1110 in the first direction Z. For example, as shown in FIG. 4, the first portion 1211, the first portion 1212, the second portion 1221 (or the second portion 1222), and the third portion 1230 may all be located directly below or directly above one memory block 1110 in the first direction Z.

In an implementation, as shown in FIG. 18, the memory block 1110 may include memory cells and bit lines 1113, where the memory cell may include transistors 1111 and capacitors 1112. A plurality of memory cells may be arranged in an array in the second direction X and the third direction Y.

Referring to FIG. 7, the transistor 1111 may include a semiconductor body 1111-1 and a portion of the gate structure 1111-2 corresponding to the semiconductor body 1111-1.

The semiconductor body 1111-1 may have a cubic shape. It is understood that the semiconductor body 1111-1 may have any suitable three-dimensional shape, such as a polyhedron shape or a cylinder shape. That is, a cross-section of the semiconductor body 1111-1 in a plan view (e.g., in an X-Y plane) may have a square shape, a rectangular shape (or a trapezoidal shape), a circular shape (or an elliptical shape), or any other suitable shape. The memory block 1110 may include a plurality of semiconductor bodies 1111-1. The plurality of semiconductor bodies 1111-1 are spaced apart from each other and arranged along the second direction X and the third direction Y. In an implementation, the material of the semiconductor body 1111-1 may include at least one of monocrystalline silicon, polycrystalline silicon, monocrystalline germanium, a III-V compound semiconductor material, a II-VI compound semiconductor material, or other semiconductor materials known in the art.

The semiconductor body 1111-1 and the gate structure 1111-2 may be configured to jointly form a vertical transistor, where the semiconductor body 1111-1 may be configured to form active regions of multiple channels in the vertical transistor. The gate structure 1111-2 may be located on at least a sidewall of the semiconductor body 1111-1, that is, the semiconductor body 1111-1 may be at least partially surrounded by the gate structure 1111-2. For example, the semiconductor body 1111-1 and the gate structure 1111-2 may be arranged radially from the center of the vertical transistor in this order.

The configuration in which the gate structure 1111-2 is disposed on a sidewall of the semiconductor body 1111-1, as illustrated in FIG. 7, is provided for illustrative purposes only and is not intended to be limiting. The gate structure 1111-2 may be formed on any suitable surface or region of the semiconductor body 1111-1, including, without limitation, a sidewall, top surface, bottom surface, left side, right side, or combinations thereof, depending on design requirements and fabrication considerations. Variations in placement, orientation, or configuration of the gate structure are fully encompassed within the scope of the present disclosure.

In an implementation of the present disclosure, the gate structure 1111-2 may be located on sidewalls of the semiconductor body 1111-1, and the semiconductor body 1111-1 and the gate structure 1111-2 may be configured to jointly form a multi-gate transistor (e.g., a gate-all-around (GAA) transistor, a tri-gate transistor, or a double-gate transistor). A multi-gate transistor may have a larger gate control area to achieve better channel control with a smaller sub-threshold swing. During the off-state, the leakage current of the multi-gate transistor may also be significantly reduced since the channel is fully depleted. Thus, better speed (saturated drain current)/leakage current performance can be achieved using multi-gate transistors.

In another implementation of the present disclosure, the gate structure 1111-2 may be located on a sidewall of the semiconductor body 1111-1, and the semiconductor body 1111-1 and the gate structure 1111-2 may be configured to jointly form a single-gate transistor. For example, single-gate transistors adjacent in the first direction Z may be symmetrically arranged. In the present disclosure, by providing the single-gate transistor, the density of the semiconductor body 1111-1 in the first direction Z can be significantly increased, and the difficulty of the manufacturing process can be reduced. In addition, the mirror-symmetric single-gate transistor may have a large process window, which is beneficial to reduce the spacing between the subsequently formed bit line 1113, word line and transistor, etc.

In an implementation, as shown in FIG. 7, the gate structure 1111-2 may be located on a side of the semiconductor body 1111-1 in the third direction Y. A dimension of the gate structure 1111-2 in the second direction X may be greater than a dimension of the gate structure 1111-2 in the third direction Y. For example, the gate structure 1111-2 may extend to a word line along the second direction X. As shown in FIG. 18, the bit line 1113 may be located on a side of the transistor 1111 (such as the semiconductor body 1111-1) in the first direction Z. A dimension of the bit line 1113 in the third direction Y may be greater than a dimension of the bit line 1113 in the second direction X. For example, the bit line 1113 may be connected to drains of a plurality of transistors 1111 arranged in the third direction Y (e.g., an end of the semiconductor body 1111-1 in the first direction Z). The capacitor 1112 may be located on the other side of the transistor 1111 (such as the semiconductor body 1111-1) in the first direction Z. The capacitor 1112 may be connected to the source of the transistor 1111 (e.g., the other end of the semiconductor body 1111-1 in the first direction Z).

The word lines may be configured to control switching of transistors 1111 in a row of memory cells in the second direction X. The bit line 1113 may be configured to send data to and/or receive data from memory cells in a column in the third direction Y. That is, each word line may be coupled to a corresponding row of memory cells and each bit line 1113 may be coupled to a corresponding column of memory cells. The voltage signal on the word line can control turning on or off of the transistor, thereby reading the data information stored in the capacitor 1112 through the bit line 1113, or writing the data information into the capacitor 1112 for storage through the bit line 1113.

The capacitor 1112 may include a first electrode (not shown) connected to the transistor 1111, a capacitor dielectric layer (not shown) in contact with the first electrode, and a second electrode (not shown) in contact with the capacitor dielectric layer. The capacitor 1112 may include, but is not limited to, a planar capacitor, a stack capacitor, a multi-fins capacitor, a cylinder capacitor, a trench capacitor, or a substrate-plate capacitor, among others. For example, the capacitor 1112 may be a vertical capacitor, where the first electrode, the capacitor dielectric layer, and the second electrode are stacked in the first direction Z, and the capacitor dielectric layer may be sandwiched between the first electrode and the second electrode.

In an implementation, as shown in FIG. 18, a substrate 1700 may be formed on a side of the first semiconductor structure 1100 facing away from the first interconnect layer 1300, so as to provide support for the first semiconductor structure 1100 after the structure shown in FIG. 18 is flipped 180°.

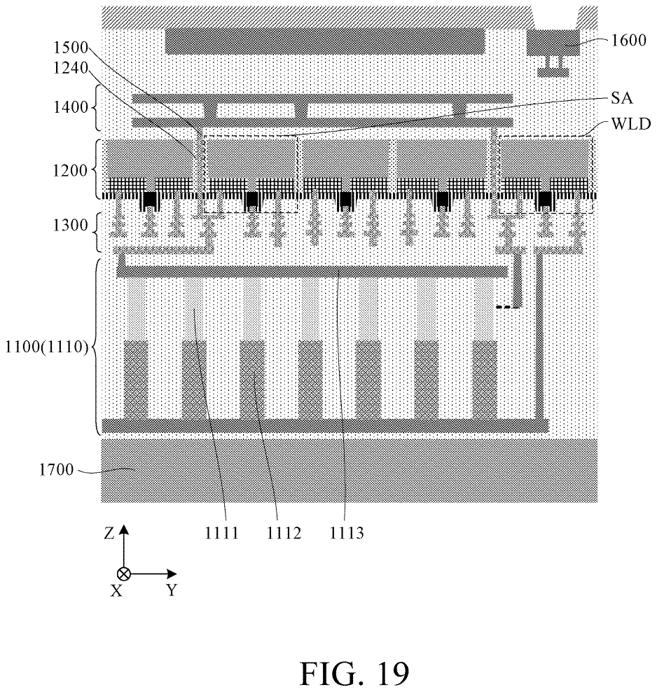

FIG. 19 is a schematic structural diagram after formation of a second interconnect layer 1400, a conductive structure 1500, and a pad structure 1600, according to some embodiments of the present disclosure.

In an implementation, the structure shown in FIG. 18 may be flipped 180° and a part of the semiconductor layer 100 may be removed until the isolation structure 1240 is exposed; a conductive structure 1500 extending through the isolation structure 1240 in the first direction Z and extending to the first interconnect layer 1300 is formed; a second interconnect layer 1400 is formed on a side of the conductive structure 1500 facing away from the first interconnect layer 1300; and a pad structure 1600 is formed on a side of the second interconnect layer 1400 facing away from the conductive structure 1500. The circuit in the third portion may be connected to the second interconnect layer 1400 via the first interconnect layer 1300 and the conductive structure 1500.

The second interconnect layer 1400 may include a plurality of metal layers (for forming interconnect lines) spaced apart from each other in the first direction Z in the dielectric layer and an interconnect structure connecting the multilayer interconnect lines. The interconnect lines and interconnect structures in the second interconnect layer 1400 may include conductive materials including, but not limited to, tungsten, copper, aluminum, doped silicon, silicide, or any combination thereof. The dielectric layer may be formed of a dielectric material including, but not limited to, silicon oxide, silicon nitride, silicon oxynitride, a low dielectric constant material layer, or any combination thereof.

The conductive structure 1500 may include a conductive material, including, but not limited to, tungsten, copper, aluminum, doped silicon, silicide, or any combination thereof. The isolation structure 1240 may include an insulating material, for example, including but not limited to silicon oxide or silicon nitride. In the present disclosure, by providing the conductive structure 1500, the routing process of wirings between the first interconnect layer 1300 and the second interconnect layer 1400 is simplified, and the routing difficulty is reduced.

In an implementation, a power line (not shown) may also be formed on a side of the second interconnect layer 1400 facing away from the conductive structure 1500. The pad structure 1600 may be located on a side of the power line facing away from the second interconnect layer 1400. In other words, the power line may be located between the second interconnect layer 1400 and the pad structure 1600. The pad structure 1600 may route electrical signals between the semiconductor device and an external circuit.

In the present disclosure, the power line is provided on the side of the second interconnect layer 1400 facing away from the second semiconductor structure 1200, which facilitates shortening the length of the interconnect structure between the second semiconductor structure 1200 and the power line, thereby reducing the parasitic capacitance of the interconnect structure and improving the sensing tolerance and storage density of the semiconductor device.

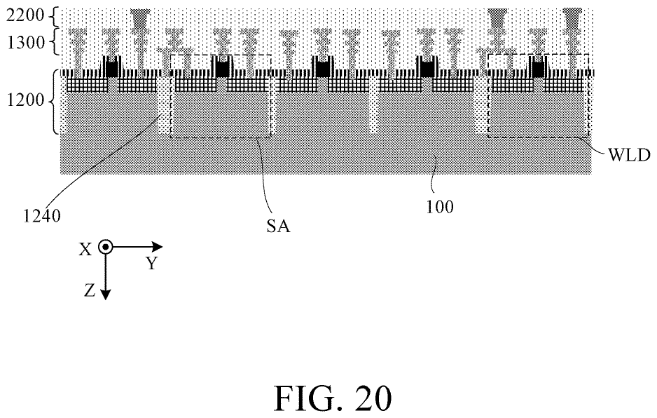

FIGS. 20 to 22 are diagrams of process operations of manufacturing a semiconductor device according to still another implementation of the present disclosure. In this implementation, for the sake of brevity, some similar descriptions as in the implementations shown in FIGS. 17 to 19 will be omitted.

In an implementation, as shown in FIG. 20, a second semiconductor structure 1200 may be formed on a side of the semiconductor layer 100; a first interconnect layer 1300 may be formed on a side of the second semiconductor structure 1200 facing away from the semiconductor layer 100 in the first direction Z; and a second bonding layer 2200 may be formed on a side of the first interconnect layer 1300 facing away from the second semiconductor structure 1200.

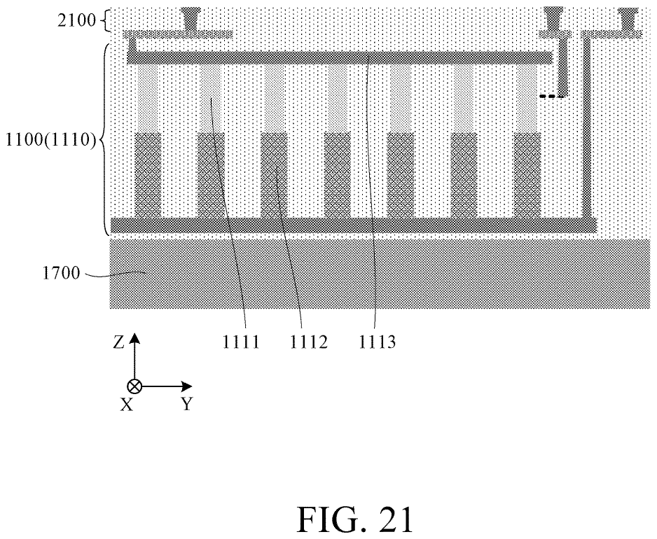

In an implementation, as shown in FIG. 21, a first semiconductor structure 1100 may be formed on a side of the substrate 1700; and a first bonding layer 2100 may be formed on a side of the first semiconductor structure 1100 facing away from the substrate 1700.

The first bonding layer 2100 and the second bonding layer 2200 may each include a bonding structure and a dielectric that isolates the bonding structure. The bonding structure may include a conductive material, including, but not limited to, tungsten, copper, aluminum, doped silicon, silicide, or any combination thereof. The dielectric may be formed of a dielectric material including, but not limited to, silicon oxide, silicon nitride, silicon oxynitride, a low dielectric constant material layer, or any combination thereof.

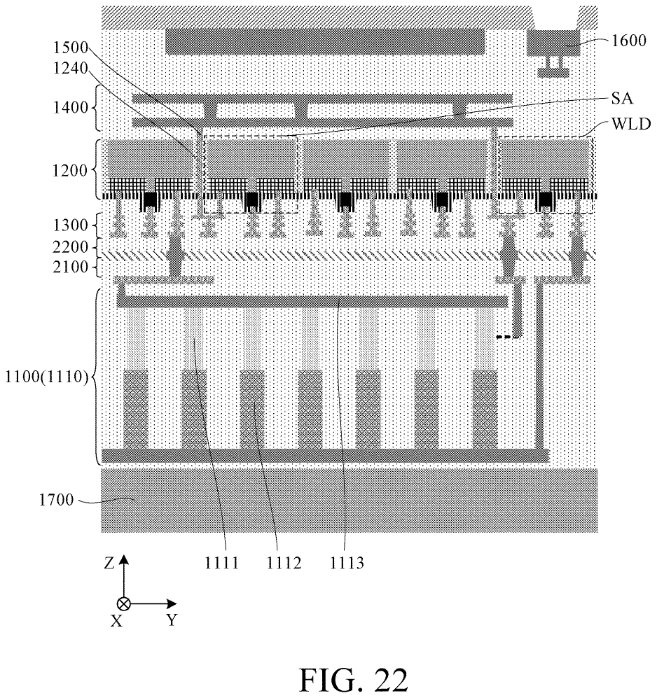

In an implementation, as shown in FIG. 22, the first semiconductor structure 1100 and the second semiconductor structure 1200 may be bonded. For example, the first bonding layer 2100 and second bonding layer 2200 may be bonded by one or more bonding processes, to bond the first semiconductor structure 1100 and the second semiconductor structure 1200.

In an implementation, as shown in FIG. 22, after the first semiconductor structure 1100 and the second semiconductor structure 1200 are bonded, a part of the semiconductor layer 100 may be removed until the isolation structure 1240 is exposed; a conductive structure 1500 extending through the isolation structure 1240 in the first direction Z and extending to the first interconnect layer 1300 is formed; a second interconnect layer 1400 is formed on a side of the conductive structure 1500 facing away from the first interconnect layer 1300; and a pad structure 1600 is formed on a side of the second interconnect layer 1400 facing away from the conductive structure 1500. The circuit in the third portion may be connected to the second interconnect layer 1400 via the first interconnect layer 1300 and the conductive structure 1500.

Since the contents and structures involved in the semiconductor devices 1000, 2000 described above may be fully or partially applicable to the method 3000 for manufacturing the semiconductor device described herein, relevant or similar contents are not repeated herein.

Although an example structure and method of manufacturing the semiconductor device are described herein, it is understood that one or more features may be omitted, replaced, or added from the method of manufacturing the semiconductor device. In addition, the illustrated layers and materials thereof are merely examples.

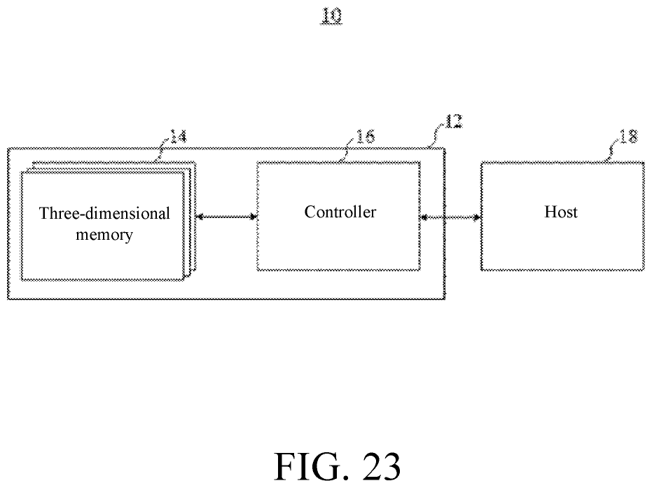

FIG. 23 is an example block diagram of a system 10 having a memory system 12, according to some embodiments of the present disclosure.

The system 10 may be a mobile phone, a desktop computer, a laptop, a tablet, a vehicle computer, a game console, a printer, a positioning device, a wearable electronic device, a smart sensor, a virtual reality (VR) device, an augmented reality (AR) device, or any other suitable electronic device having a memory system 12 therein. As shown in FIG. 23, the system 10 may include a host 18 and a memory system 12 having one or more semiconductor devices, for example, which may include a three-dimensional memory 14, and a controller 16. The host 18 may be a processor of an electronic device, such as a central processing unit (CPU), or may be a system-on-chip (SoC), such as an application processor (AP). The host 18 may be configured to send or receive data to or from the three-dimensional memory 14.

The three-dimensional memory 14 may include the semiconductor device described in any implementation of the present disclosure. According to some implementations, the controller 16 is coupled to the three-dimensional memory 14 and the host 18, and is configured to control the three-dimensional memory 14. The controller 16 may manage data stored in the three-dimensional memory 14 and communicate with the host 18. For example, controller 16 may communicate with an external device (e.g., host 18) according to a particular communication protocol.

The above description is only a description of some implementations of the present disclosure and the applied technical principles. Those skilled in the art should understand that the scope of the present disclosure is not limited to the technical solutions formed by specific combination of the above technical features, and should also encompass other technical solutions formed by any combination of the above technical features or their equivalent features without departing from the inventive concept, for example, the technical solutions formed by replacing the above features with (but not limited to) technical features with similar functions disclosed in the present disclosure.

What is claimed is:

1. A semiconductor device, comprising:
a first semiconductor structure comprising a memory block; and
a second semiconductor structure located on a first side of the first semiconductor structure in a first direction and comprising:
two first portions located on a second side of the memory block in the first direction;
a second portion located on a third side of the memory block in the first direction and located on a fourth side of the first portions in a second direction or a third direction; and
a third portion located on a fifth side of the memory block in the first direction,
wherein the two first portions are spaced apart from each other in the third direction, and the third portion is located between the two first portions,
the two first portions, the second portion, and the third portion comprise different circuits, and
the first direction, the second direction, and the third direction intersect with each other.

2. The semiconductor device of claim 1, wherein the second semiconductor structure comprises two second portions comprising the second portion and spaced apart from each other in the second direction, and
wherein the two second portions are located between the two first portions.

3. The semiconductor device of claim 2, wherein a first portion of the two first portions comprises a first end and a second end opposite to each other in the second direction, and
wherein a dimension of the first end in the third direction is different from a dimension of the second end in the third direction.

4. The semiconductor device of claim 2, wherein a dimension of the first portion in the second direction is the same as a dimension of the third portion in the second direction, and
wherein a part of the third portion is located on at least a sixth side of the second portions in the third direction, and a remaining part of the third portion is located between the two second portions.

5. The semiconductor device of claim 1, wherein the second semiconductor structure comprises two second portions comprising the second portion and spaced apart from each other in the second direction, and
wherein the two second portions are located on two sides of the two first portions and the third portion in the second direction, respectively.

6. The semiconductor device of claim 5, wherein a dimension of the first portion in the second direction is the same as a dimension of the third portion in the second direction.

7. The semiconductor device of claim 5, wherein the second portion is located at an end of the first portion in the second direction.

8. The semiconductor device of claim 7, wherein the first portion comprises a first end and a second end opposite to each other in the second direction, and
wherein a dimension of the first end in the third direction is the same as a dimension of the second end in the third direction.

9. The semiconductor device of claim 8, wherein the first portion further comprises an intermediate portion between the first end and the second end, and
wherein a dimension of the first end in the third direction is greater than a dimension of the intermediate portion in the third direction.

10. The semiconductor device of claim 1, wherein a dimension of a first portion of the two first portions in the second direction is greater than a dimension of the first portion in the third direction, and a dimension of the second portion in the third direction is greater than a dimension of the second portion in the second direction.

11. The semiconductor device of claim 1, wherein the memory block comprises:
a semiconductor body;
a gate structure located on a sixth side of the semiconductor body in the third direction, wherein a dimension of the gate structure in the second direction is greater than a dimension of the gate structure in the third direction; and
a bit line located on a seventh side of the semiconductor body in the first direction, wherein a dimension of the bit line in the third direction is greater than a dimension of the bit line in the second direction,
wherein a circuit in a first portion of the two first portions comprises a sense amplifier circuit, and a circuit in the second portion comprises a word line driver circuit, and
wherein the sense amplifier circuit is connected to the bit line, and the word line driver circuit is connected to the gate structure.

12. A semiconductor device, comprising:
a first semiconductor structure comprising a first memory block and a second memory block adjacent to each other; and
a second semiconductor structure located on a first side of the first semiconductor structure in a first direction and comprising:
a first portion located on a second side of the first memory block in the first direction;
a second portion located on a third side of the second memory block in the first direction; and
a third portion comprising a first sub-portion and a second sub-portion, wherein the first sub-portion is located on a fourth side of the first memory block in the first direction, and the second sub-portion is located on a fifth side of the second memory block in the first direction,
wherein the first memory block and the second memory block are adjacent to each other in a second direction or a third direction,
the first portion, the second portion, and the third portion comprise different circuits, and
the first direction, the second direction, and the third direction intersect with each other.

13. The semiconductor device of claim 12, wherein the first sub-portion is further located on two sides of the first portion in the third direction.

14. The semiconductor device of claim 12, wherein a dimension of the first sub-portion in the second direction is the same as a dimension of the first portion in the second direction.

15. The semiconductor device of claim 12, wherein the second semiconductor structure comprises two second portions comprising the second portion and spaced apart from each other in the second direction, and
wherein a part of the second sub-portion is located on at least a sixth side of the second portions in the third direction, and a remaining part of the second sub-portion is located between the two second portions.

16. The semiconductor device of claim 15, wherein a dimension of the second portion in the third direction is smaller than a dimension of the second memory block in the third direction.

17. The semiconductor device of claim 12, wherein the second semiconductor structure comprises two first portions comprising the first portion and spaced apart from each other in the third direction, and
wherein the first sub-portion is located between the two first portions, and a dimension of the first sub-portion in the second direction is the same as a dimension of the first portion in the second direction.

18. The semiconductor device of claim 12, wherein the second semiconductor structure comprises two second portions comprising the second portion and spaced apart from each other in the second direction, and
wherein the second sub-portion is located between the two second portions, and a dimension of the second portion in the third direction is the same as a dimension of the second memory block in the third direction.

19. The semiconductor device of claim 12, wherein the first memory block and the second memory block comprise:
a semiconductor body;
a gate structure located on a sixth side of the semiconductor body in the third direction, wherein a dimension of the gate structure in the second direction is greater than a dimension of the gate structure in the third direction; and
a bit line located on a seventh side of the semiconductor body in the first direction, wherein a dimension of the bit line in the third direction is greater than a dimension of the bit line in the second direction,
wherein a circuit in the first portion comprises a sense amplifier circuit and a circuit in the second portion comprises a word line driver circuit, and
wherein the sense amplifier circuit is connected to the bit line, and the word line driver circuit is connected to the gate structure.

20. A memory system, comprising:
a semiconductor device, comprising:
a first semiconductor structure comprising a memory block; and
a second semiconductor structure located on a first side of the first semiconductor structure in a first direction and comprising:
two first portions located on a second side of the memory block in the first direction;
a second portion located on a third side of the memory block in the first direction and located on a fourth side of the first portions in a second direction or a third direction; and
a third portion located on a fifth side of the memory block in the first direction,
wherein the two first portions are spaced apart from each other in the third direction, and the third portion is located between the two first portions,
the two first portions, the second portion, and the third portion comprise different circuits, and
the first direction, the second direction, and the third direction intersect with each other; and
a controller coupled to the semiconductor device and configured to control the semiconductor device to store data.
